(19) United States
(12) Patent Application Publication
(10) Pub. No.: US 2024/0385047 A1
(43) Pub. Date: Nov. 21, 2024

(54) INFRARED SENSOR, COMBINATION SENSOR, AND ELECTRONIC DEVICE INCLUDING THE SAME

(71) Applicants: Samsung Electronics Co., Ltd., Suwon-si (KR); PUSAN NATIONAL UNIVERSITY INDUSTRY-UNIVERSITY COOPERATION FOUNDATION, Busan (KR)

(72) Inventors: Sang Ho PARK, Suwon-si (KR); Sangdong KIM, Suwon-si (KR); Balamurugan GOPAL, Busan (KR); Rae Sung KIM, Suwon-si (KR); Se Jeong PARK, Busan (KR); Insun PARK, Suwon-si (KR); Jongseung PARK, Busan (KR); Dong-Seok LEEM, Suwon-si (KR); Jae Woong JANG, Busan (KR)

(73) Assignees: Samsung Electronics Co., Ltd., Suwon-si (KR); PUSAN NATIONAL UNIVERSITY INDUSTRY-UNIVERSITY COOPERATION FOUNDATION, Busan (KR)

(21) Appl. No.: 18/658,028

(22) Filed: May 8, 2024

(30) Foreign Application Priority Data
May 9, 2023 (KR) 10-2023-0060164

(51) Int. Cl. G01J 5/10; C07F 3/06; C07F 7/22; C07F 13/00

(52) U.S. Cl. CPC G01J 5/10; C07F 3/06; C07F 7/2284; C07F 13/005

(57) ABSTRACT

Provided are a compound, an infrared sensor, a combination sensor, and an electronic device. The compound is represented by Chemical Formula 1. The infrared sensor includes a first electrode and a second electrode facing each other, and an infrared photoelectric conversion layer between the first electrode and the second electrode, wherein the infrared photoelectric conversion layer includes the compound represented by Chemical Formula 1.

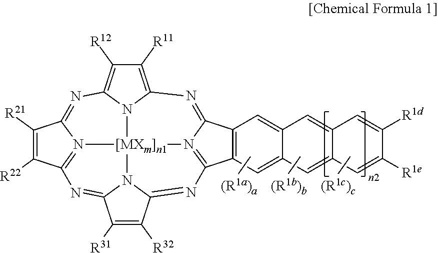

In Chemical Formula 1, the definition of each substituent is as described in the detailed description.

### CROSS-REFERENCE TO RELATED APPLICATION

This application claims priority to and the benefit under 35 U.S.C. § 119 of Korean Patent Application No. 10-2023-0060164 filed in the Korean Intellectual Property Office on May 9, 2023, the entire contents of which are incorporated herein by reference.

### BACKGROUND

### 1. Field

Infrared sensors, combination sensors, and electronic devices are disclosed.

### 2. Description of the Related Art

An imaging device is used in a digital camera and a camcorder or the like to take an image and to store the same as an electrical signal, and the imaging device includes a sensor dissembling the incident light according to a wavelength and converting each component to an electrical signal.

Recently, an infrared sensor that detects light in an infrared (IR) region for improving the sensitivity of a sensor in a low illumination environment or for use as a biometric device or a security device has been studied.

### SUMMARY

Some example embodiments provide an infrared sensor including a low-molecular-weight compound with excellent infrared absorption characteristics and excellent deposition stability.

Some example embodiments provide a combination sensor including the infrared sensor.

Some example embodiments provide an electronic device including the infrared sensor or the combination sensor.

According to some example embodiments, an infrared sensor may include a first electrode and a second electrode facing each other, and an infrared photoelectric conversion layer between the first electrode and the second electrode, wherein the infrared photoelectric conversion layer includes a compound represented by Chemical Formula 1.

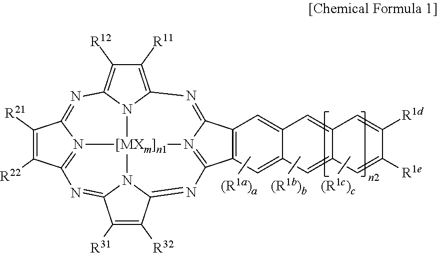

In Chemical Formula 1,
M may be a divalent metal, a trivalent metal, or a tetravalent metal,
X may be a halogen,
m may be an integer from 0 to 4,
n1 may be 0 or 1,
R^{1a}, R^{1b}, R^{1c}, R^{1d}, and R^{1e} may each independently be hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof,
a, b, and c may each independently be an integer from 0 to 2,
n2 may be 1 or 2, and
R¹¹, R¹², R²¹, R²², R³¹, and R³² may each independently be hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof, or at least one pair of a pair of R¹¹ and R¹², a pair of R²¹ and R²², or a pair of R³¹ and R³² are may be optionally linked to each other to form a substituted or unsubstituted benzene ring or a substituted or unsubstituted naphthalene ring.

In Chemical Formula 1, M may be a transition metal.

In Chemical Formula 1, M may be Zn, Mn, Sn, Co, Ru, Ni, V, Si, or Ge.

In Chemical Formula 1, any one of R^{1a}, R^{1b}, R^{1d}, R^{1e}, R¹¹, R¹², R²¹, R²², R³¹ and R³² may be a C6 to C20 haloalkyl group, a C6 to C20 cyanoalkyl group, a C6 to C20 alkyl group, a hydroxy group, or a C6 to C20 alkoxy group.

In Chemical Formula 1, at least one of R^{1a}, R^{1b}, R^{1d}, R^{1e}, R¹¹, R¹², R²¹, R²², R³¹, or R³² may be a C6 to C20 haloalkyl group, a C6 to C20 cyanoalkyl group, a C6 to C20 alkyl group, a hydroxy group, or a C6 to C20 alkoxy group, or a C3 to C22 alkylene glycol-derived group (*—O—[(CH₂)₂—O]ₙ—R, wherein R is a C1 to C20 alkyl group and n is an integer of 1 to 10).

A molecular weight of the compound represented by Chemical Formula 1 may be less than or equal to about 900.

The compound represented by Chemical Formula 1 may have a permanent dipole moment of greater than or equal to about 1.2 Debye.

The compound represented by Chemical Formula 1 may have an aspect ratio of greater than about 2.0 and less than or equal to about 8.0.

An angle between a permanent dipole moment (PDM) direction and a z-axis of the compound represented by Chemical Formula 1 may be greater than or equal to about 30 degrees, for example, greater than or equal to about 45 degrees.

The compound represented by Chemical Formula 1 may have a sublimation temperature of less than or equal to about 500° C., wherein the sublimation temperature refers to a temperature at which a weight loss of the compound represented by Chemical Formula 1 of 5% compared to an initial weight of the compound represented by Chemical Formula 1 occurs when thermogravimetric analysis of the compound represented by Chemical Formula 1 occurs at 10 Pa or less.

A maximum external quantum efficiency (EQEₘₐₓ) wavelength of the infrared sensor may be in a wavelength range of about 800 nm to about 3000 nm.

The infrared photoelectric conversion layer may further include a counter material that forms a pn junction with the compound.

The infrared sensor may further include an auxiliary layer that is at least one of between the first electrode and the infrared photoelectric conversion layer or between the second electrode and the infrared photoelectric conversion layer.

The auxiliary layer may include ytterbium (Yb), calcium (Ca), potassium (K), barium (Ba), magnesium (Mg), lithium fluoride (LiF), or an alloy thereof.

The infrared sensor may further include a semiconductor substrate.

According to some example embodiments, a combination sensor may include a first infrared sensor that is the aforementioned infrared sensor and a second infrared sensor configured to sense light in a shorter wavelength region or a longer wavelength region than the first infrared sensor within an infrared wavelength region, wherein the first infrared sensor and the second infrared sensor may be stacked in a depth direction that is perpendicular to an in-plane direction of the first infrared sensor.

According to some example embodiments, a combination sensor includes the infrared sensor and a visible light sensor configured to sense at least a portion of light in a visible light wavelength region.

The combination sensor may further include a semiconductor substrate, and the infrared sensor may be arranged in parallel with the visible light sensor along an in-plane direction of the semiconductor substrate, or may be stacked with the visible light sensor along a depth direction of the semiconductor substrate.

The visible light sensor may include a blue sensor configured to sense light in a blue wavelength region, a green sensor configured to sense light in a green wavelength region, and a red sensor configured to sense light in a red wavelength region, and each of the blue sensor, the green sensor, and the red sensor may be a photodiode integrated in a semiconductor substrate.

The visible light sensor may include a blue sensor configured to sense light in a blue wavelength region, a green sensor configured to sense light in a green wavelength region, and a red sensor configured to sense light in a red wavelength region, wherein two of the blue sensor, the green sensor, and the red sensor may be photodiodes integrated in a semiconductor substrate, and the other of the blue sensor, the green sensor, and the red sensor may be a visible light photoelectric conversion device on the semiconductor substrate and stacked with the infrared sensor in a depth direction that is perpendicular to an in-plane direction of the infrared sensor.

The visible light sensor may include a blue sensor configured to sense light in a blue wavelength region, a green sensor configured to sense light in a green wavelength region, and a red sensor configured to sense light in a red wavelength region, and each of the blue sensor, the green sensor, and the red sensor may be a visible light photoelectric conversion device stacked with the infrared sensor.

According to some example embodiments, an electronic device including the infrared sensor or the combination sensor is provided.

An infrared sensor containing a compound with good light absorption properties and excellent deposition stability in the infrared wavelength region is provided.

According to some example embodiments, a compound (infrared absorbing material) may be represented by Chemical Formula 1:

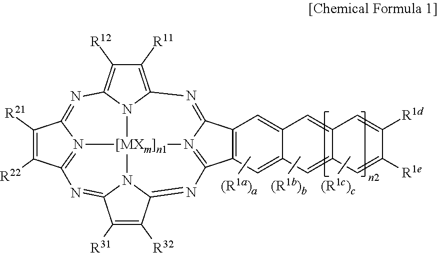

wherein, in Chemical Formula 1,
M is a divalent metal, a trivalent metal, or a tetravalent metal,
X is a halogen,
m is an integer from 0 to 4,
n1 is 0 or 1,
R^{1a}, R^{1b}, R^{1c}, R^{1d}, and R^{1e} are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof,
a, b, and c are each independently an integer from 0 to 2,
n2 is 1 or 2, and
R¹¹, R¹², R²¹, R²², R³¹, and R³² are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof, or at least one pair of a pair of R¹¹ and R¹², a pair of R²¹ and R²², or a pair of R³¹ and R³² are linked to each other to form a substituted or unsubstituted benzene ring or a substituted or unsubstituted naphthalene ring.

In Chemical Formula 1, M may be a transition metal.

In Chemical Formula 1, M may be Zn, Mn, Sn, Co, Ru, Ni, V, Si, or Ge.

The compound may have at least one of a molecular weight that is less than or equal to about 900, a permanent dipole moment of greater than or equal to about 1.2 Debye, or an aspect ratio of greater than about 2.0 and less than or equal to about 8.0.

### BRIEF DESCRIPTION OF THE DRAWINGS

FIG. 1 is a cross-sectional view showing an example of an infrared sensor according to some example embodiments,

FIG. 2 is a cross-sectional view showing an example of a CMOS infrared sensor according to some example embodiments,

FIG. 3 is a cross-sectional view showing an example of a combination sensor according to some example embodiments,

FIG. 4 is a cross-sectional view showing an example of a combination sensor according to some example embodiments,

FIG. 5 is a cross-sectional view showing an example of a combination sensor according to some example embodiments,

FIG. 6 is a cross-sectional view schematically showing an example of a combination sensor according to some example embodiments,

FIG. 7 is a cross-sectional view schematically showing an example of a combination sensor according to some example embodiments,

FIG. 8 is a perspective view schematically showing an example of a combination sensor according to some example embodiments,

FIG. 9 is a cross-sectional view schematically showing an example of the combination sensor along view line IX-IX′ in FIG. 8 according to some example embodiments,

FIG. 10 is a perspective view schematically showing an example of a combination sensor according to some example embodiments,

FIG. 11 is a cross-sectional view schematically showing an example of the combination sensor of FIG. 10 according to some example embodiments,

FIG. 12 is a schematic view of an electronic device according to some example embodiments, and

FIG. 13 shows the results of measuring the external quantum efficiency of the infrared sensor according to Comparative Example 1.

### DETAILED DESCRIPTION

Hereinafter, example embodiments will be described in detail so that those of ordinary skill in the art can easily implement them. However, a structure that is actually applied may be implemented in various different forms, and is not limited to the example embodiments described herein.

In the drawings, the thickness of layers, films, panels, regions, etc., are exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%)

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%). It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof. When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

As used herein, when a definition is not otherwise provided, “substituted” refers to replacement of hydrogen of a compound or a group by a substituent selected from a halogen atom, a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a silyl group, a C1 to C20 alkyl group, a C2 to C20 alkenyl group, a C2 to C20alkynyl group, a C6 to C30 aryl group, a C7 to C30 arylalkyl group, a C1 to C30 alkoxy group, a C1 to C30 thioalkoxy group, a C1 to C20 heteroalkyl group, a C3 to C20heteroaryl group, a C3 to C20 heteroarylalkyl group, a C3 to C30 cycloalkyl group, a C3 to C15 cycloalkenyl group, a C6 to C15 cycloalkynyl group, a C3 to C30heterocycloalkyl group, and any combination thereof.

As used herein, when a definition is not otherwise provided, “aryl group” refers to a group including at least one hydrocarbon aromatic moiety. All elements of the hydrocarbon aromatic moiety have p-orbitals which form conjugation, for example a phenyl group, a naphthyl group, and the like, two or more hydrocarbon aromatic moieties may be linked by a sigma bond and may be, for example a biphenyl group, a terphenyl group, a quarterphenyl group, and the like, and two or more hydrocarbon aromatic moieties may be fused directly or indirectly to provide a non-aromatic fused ring, for example a fluorenyl group. The aryl group may include a monocyclic, polycyclic or fused polycyclic (i.e., rings sharing adjacent pairs of carbon atoms) functional group.

As used herein, when a definition is not otherwise provided, “hetero” refers to one including 1 to 4 heteroatoms selected from N, O, S, Se, Te, Si, and P.

As used herein, when a definition is not otherwise provided, “heteroaryl group” refers to an aryl group containing at least one hetero atom selected from N, O, S, Se, Te, P and Si instead of carbon (C) in the aromatic ring. When the heteroaryl group is a fused ring, each aromatic ring may have at least one heteroatom. Examples of the heteroaryl groups may include a heteropyrrolyl group, a pyrazolyl group, an imidazolyl group, an oxazolyl group, an isoxazolyl group, a thiazolyl group. group, an isothiazolyl group, a pyridinyl group, a pyridazinyl group, a pyrimidinyl group, a pyrazinyl group, an indolyl group, a quinolinyl group, an isoquinolinyl group, a naphthyridinyl group, a cinnolinyl group, a quinazolinyl group, a phthalazinyl group, a benzotriazinyl group, a pyridopyrazinyl group, a pyridopyrimidinyl group, a pyridopyridazinyl group, a thienyl group, a benzothienyl group, a selenophenyl group, or a benzoselenophenyl group.

As used herein, when a definition is not otherwise provided, “cycloalkyl group” refers to an alicyclic cyclic group, for example, a C3 to C30 cycloalkyl group or a C3to C20 cycloalkyl group.

As used herein, when a definition is not otherwise provided, “heterocycloalkyl group” refers to a cycloalkyl group containing at least one heteroatom selected from N, O, S, Se, Te, P, and Si instead of carbon (C) in the alicyclic ring. That is, it means that some of the hydrogen atoms of the cycloalkyl group are substituted with an alkyl group, but contain a heteroatom. Examples of the cycloalkyl groups may include an aziridinyl group, a pyrrolidinyl group, a piperidinyl group, a piperazinyl group, a morpholinyl group, a thiomorpholinyl group, a tetrahydrofuranyl group, a tetrahydrothiofuranyl group, a tetrahydropyranyl group, and a pyranyl group.

As used herein, “alkyl group” refers to a monovalent linear or branched saturated hydrocarbon group, for example, a methyl group, an ethyl group, a propyl group, an isopropyl group, an n-butyl group, an isobutyl group, a t-butyl group, a pentyl group, a hexyl group, and the like.

As used herein, when a definition is not otherwise provided, “alkoxy group” refers to a group represented by —OR, wherein R may be the alkyl group described above.

As used herein, when a definition is not otherwise provided, “thioalkyl group” refers to a group represented by —SR, wherein R may be the alkyl group described above.

As used herein, when a definition is not otherwise provided, “amine group” is a group represented by —NRR′, wherein R and R′ may each independently be hydrogen, deuterium, a C1 to C20 alkyl group, or a C6 to C20 aryl group.

As used herein, when a definition is not otherwise provided, “ester group” refers to a group represented by —C(═O)OR, wherein R is a C1 to C20 alkyl group or a C6 to C20 aryl group.

As used herein, when a definition is not otherwise provided, “amide group” refers to a group represented by —C(═O) NR, wherein R may be a C1 to C20 alkyl group or a C6 to C20 aryl group.

As used herein, when a definition is not otherwise provided, “thioester group” refers to a group represented by —C(═O) SR, wherein R may be a C1 to C20 alkyl group or a C6 to C20 aryl group.

As used herein, when a definition is not otherwise provided, “combination” refers to a mixture, a stack, or an alloy of constituting components.

As used herein, when a definition is not otherwise provided, “combination thereof” in the definition of chemical formula refers to at least two substituents bound to each other by a single bond or a C1 to C10 alkylene group, or at least two fused substituents.

Hereinafter, a work function, a HOMO energy level, or a LUMO energy level is expressed as an absolute value from a vacuum level. In addition, when the work function, HOMO energy level, or LUMO energy level is referred to be deep, high, or large, it may have a large absolute value based on “0 eV” of the vacuum level while when the work function, HOMO energy level, or LUMO energy level is referred to be shallow, low, or small, it may have a small absolute value based on “0 eV” of the vacuum level.

A HOMO energy level is evaluated by irradiating UV light to the thin film with AC-2 (Hitachi) or AC-3 (Riken Keiki Co., Ltd.) to measure a dose of photoelectrons emitted according to energy.

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

As used herein, when a definition is not otherwise provided, “metal” may include a metal and a semimetal.

Hereinafter, an infrared sensor according to some example embodiments will be described with reference to the drawings.

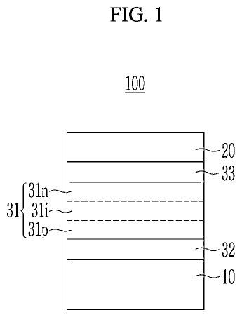

FIG. 1 is a cross-sectional view showing an example of an infrared sensor according to some example embodiments.

Referring to FIG. 1, an infrared sensor 100 according to some example embodiments may be an infrared photoelectric conversion device and may include a first electrode 10 and a second electrode 20 facing each other, and an infrared photoelectric conversion layer 31 between the first electrode 10 and the second electrode 20, wherein the infrared photoelectric conversion layer 31 may include a compound represented by Chemical Formula 1.

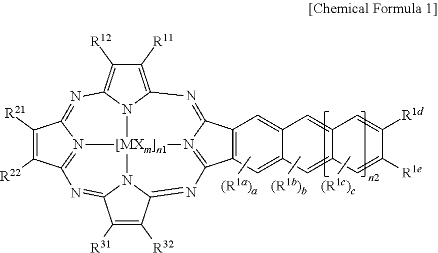

In Chemical Formula 1,
M may be a divalent metal, a trivalent metal, or a tetravalent metal,
X may be a halogen,
m may be an integer from 0 to 4,
n1 may be 0 or 1,
R^{1a}, R^{1b}, R^{1c}, R^{1d}, and R^{1e} may each independently be hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof,
a, b, and c are each independently an integer from 0 to 2,
n2 is 1 or 2, and
R¹¹, R¹², R²¹, R²², R³¹, and R³² are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof, or at least one pair of a pair of R¹¹ and R¹², a pair of R²¹ and R²², or a pair of R³¹ and R³² may be optionally linked to each other to form a substituted or unsubstituted benzene ring or a substituted or unsubstituted naphthalene ring.

The infrared sensor may sense at least some light in the infrared wavelength region, for example, selectively absorb at least some of the infrared wavelength region and thus convert it (the selectively absorbed light) into electrical signals. The infrared sensor may exhibit an absorption spectrum having a maximum absorption wavelength in the infrared wavelength region. Each infrared sensor may independently include a photo-sensing device such as a photodiode or a photoelectric conversion device, and may be, for example, a photoelectric conversion device.

A substrate (not shown) may be disposed at the side of the first electrode 10 or the second electrode 20. The first electrode 10 may be on (e.g., above or beneath) the substrate. The second electrode 20 may be on (e.g., above or beneath) the substrate. The substrate may be, for example, made of an inorganic material such as glass, an organic material such as polycarbonate, polymethylmethacrylate, polyethylene terephthalate, polyethylene naphthalate, polyamide, polyethersulfone, or any combination thereof, or a silicon wafer. The substrate may be a semiconductor substrate. The substrate may be omitted.

One of the first electrode 10 or the second electrode 20 may be an anode and the other one of the first electrode 10 or the second electrode 20 may be a cathode. For example, the first electrode 10 may be an anode and the second electrode 20 may be a cathode. For example, the first electrode 10 may be a cathode and the second electrode 20 may be an anode.

At least one of the first electrode 10 or the second electrode 20 may be a (semi) light-transmitting electrode, and the (semi) light-transmitting electrode may be made of a thin single layer or multiple layers of a metal thin film including a conductive oxide such as indium tin oxide (ITO), indium zinc oxide (IZO), zinc oxide (ZnO), tin oxide (SnO₂), aluminum tin oxide (AlTO), and fluorine doped tin oxide (FTO) or silver (Ag), copper (Cu), aluminum (Al), magnesium (Mg), magnesium-silver (Mg—Ag), magnesium-aluminum (Mg—Al), or any combination thereof.

For example, both the first electrode 10 and the second electrode 20 may be (semi) light-transmitting electrodes. For example, the second electrode 20 may be a light receiving electrode disposed on a side that receives light (e.g., a light-incident side of the infrared sensor 100).

As an example, one of the first electrode 10 or the second electrode 20 may be a (semi) light-transmitting electrode and the other may be a reflective electrode. The reflective electrode may include a reflective layer including an optically opaque material, and the reflective layer may have a light transmittance of less than about 10%, less than or equal to about 8%, less than or equal to about 7%, less than or equal to about 5%, less than or equal to about 3%, or less than or equal to about 1% and/or may have a light transmittance equal to or greater than 0%, equal to or greater than about 0.01%, equal to or greater than about 0.1%, or equal to or greater than about 1%, and a reflectance of greater than or equal to about 10%, greater than or equal to about 20%, greater than or equal to about 30%, greater than or equal to about 50%, or greater than or equal to about 70% and/or may have a reflectance equal to or less than about 100%, equal to or less than about 90%, or equal to less than about 80%. The optically opaque material may include a metal, a metal nitride, or any combination thereof, such as silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto. The reflective layer may be one layer or two or more layers.

The infrared photoelectric conversion layer 31 may be configured to absorb light in an infrared wavelength region and photoelectrically convert the absorbed light into an electrical signal. The infrared photoelectric conversion layer 31 may include a p-type semiconductor and an n-type semiconductor forming a pn junction, and the infrared photoelectric conversion layer 31 may be configured to generate excitons based on receiving light from the outside (e.g., incident light that is incident on the infrared photoelectric conversion layer 31 from an exterior of the infrared photoelectric conversion layer 31), and then separating the generated excitons into holes and electrons.

The p-type semiconductor and/or the n-type semiconductor may be a light absorbing material configured to absorb light in at least a portion of a wavelength region (e.g., an infrared wavelength region, a visible wavelength region, an ultraviolet wavelength region, or any combination thereof). For example, the compound represented by Chemical Formula 1 may be included as a p-type semiconductor or an n-type semiconductor in the infrared photoelectric conversion layer 31, and the infrared photoelectric conversion layer 31 may further include a counterpart material forming a pn junction with the compound represented by Chemical Formula 1 in the infrared photoelectric conversion layer 31. The counterpart material may be for example a light absorbing material or a non-light absorbing material. For example, the compound represented by Chemical Formula 1 may be used as a p-type semiconductor, and the photoelectric conversion layer may further include an n-type semiconductor forming a pn junction with the compound represented by Chemical Formula 1. The n-type semiconductor may include fullerene or a fullerene derivative. For example, the compound represented by Chemical Formula 1 may be used as an n-type semiconductor, and the photoelectric conversion layer may further include a p-type semiconductor forming a pn junction with the compound represented by Chemical Formula 1.

As described herein, examples of the fullerene may include C60, C70, C76,C78, C80, C82, C84, C90, C96, C240, C540, a mixture thereof, a fullerene nanotube, and the like. The fullerene derivative may refer to compounds of these fullerenes having a substituent thereof. The fullerene derivative may include a substituent such as an alkyl group (e.g., C1 to C30 alkyl group), an aryl group (e.g., C6 to C30 aryl group), a heterocyclic group (e.g., C3 to C30 heterocycloalkyl group), and the like. Examples of the aryl groups and heterocyclic groups may be a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, a isobenzofuran ring, a benzimidazole ring, a imidazopyridine ring, a quinolizidine ring, a quinoline ring, a phthalazine ring, a naphthyridine ring, a quinoxaline ring, an isoquinoline ring, a carbazole ring, a phenanthridine ring, an acridine ring, a phenanthroline ring, a thianthrene ring, a chromene ring, an xanthene ring, a phenoxazine ring, a phenoxathiin ring, a phenothiazine ring, or a phenazine ring.

For example, the infrared photoelectric conversion layer 31 may include an intrinsic layer (I layer) in which a p-type semiconductor and an n-type semiconductor are co-deposited. The intrinsic layer may be a mixed layer in which a p-type semiconductor and an n-type semiconductor are mixed in a form of bulk heterojunction.

For example, the p-type semiconductor and the n-type semiconductor in the intrinsic layer may be included in the infrared photoelectric conversion layer 31 in a volume ratio (thickness ratio) of about 1:9 to about 9:1, within the range for example a volume ratio (thickness ratio) of about 2:8 to about 8:2, about 3:7 to about 7:3, about 4:6 to about 6:4, or about 5:5.

For example, the p-type semiconductor in the intrinsic layer may be included in an amount that is less than that of the n-type semiconductor. For example, the composition ratio (volume ratio or thickness ratio) of the p-type semiconductor to the n-type semiconductor in the infrared photoelectric conversion layer 31 may be about 0.10 to about 0.90. The composition ratio of the p-type semiconductor to the n-type semiconductor in the infrared photoelectric conversion layer 31 may be, for example, about 0.10 to about 0.80, about 0.10 to about 0.70, about 0.10 to about 0.50, or about 0.10 to about 0.30.

The infrared photoelectric conversion layer 31 may further include a p-type layer and/or an n-type layer in addition to the intrinsic layer. The p-type layer may include the aforementioned p-type semiconductor and the n-type layer may include the aforementioned n-type semiconductor. For example, it may be included in various combinations such as a p-type layer/I layer, an I-layer/n-type layer, and a p-type layer/I-layer/n-type layer.

The main absorption spectrum of the compound may be in the infrared absorption wavelength region (the infrared absorption wavelength region may be referred to interchangeably as the infrared wavelength region), wherein the infrared absorption wavelength region may be, for example, greater than or equal to about 800nm, greater than or equal to about 810 nm, greater than or equal to about 820 nm, greater than or equal to about 830 nm, greater than or equal to about 850 nm, greater than or equal to about 870 nm, greater than or equal to about 890 nm, greater than or equal to about 900 nm, greater than or equal to about 920 nm, greater than or equal to about 940 nm, greater than or equal to about 960 nm, greater than or equal to about 980 nm, greater than or equal to about 1000 nm, greater than or equal to about 1050 nm, greater than or equal to about 1100 nm, or greater than or equal to about 1200 nm, wherein the infrared absorption wavelength region may be, for example, less than or equal to about 3000 nm, less than or equal to about 2500 nm, less than or equal to about 2200 nm, less than or equal to about 2100 nm, or less than or equal to about 2000 nm. For example, the infrared photoelectric conversion layer 31 may have a maximum absorption wavelength that belongs to (e.g., may be in) a wavelength region of about 800 nm to about 3000 nm, within the range for example about 810 nm to about 2500 nm, for example, about 820 nm to about 2200 nm, for example about 830nm to about 2100 nm, for example about 840 nm to about 2000 nm, for example about 850 nm to about 2000 nm, for example about 860 nm to about 2000 nm, for example about 870 nm to about 2000 nm, for example about 880 nm to about 2000 nm, for example about 890 nm to about 2000 nm, for example about 900 nm to about 2000nm, for example about 920 nm to about 2000 nm, for example about 940 nm to about 2000 nm, for example about 960 nm to about 2000 nm, for example about 980 nm to about 2000 nm, for example about 990 nm to about 2000 nm, for example about 1000 nm to about 2000 nm, for example about 1050 nm to about 2000 nm, or for example about 1100 nm to about 2000 nm.

The maximum external quantum efficiency (EQEₘₐₓ) wavelength of the infrared sensor may belong to (e.g., may be in) a wavelength region of about 800 nm to about 3000 nm, and within this range, for example, about 810 nm to about 2500 nm, for example, for example, about 820 nm to about 2200 nm, for example about 830 nm to about 2100 nm, for example about 840 nm to about 2000 nm, for example about 850 nm to about 2000 nm, for example about 860 nm to about 2000 nm, for example about 870 nm to about 2000 nm, for example about 880 nm to about 2000 nm, for example about 890 nm to about 2000 nm, for example about 900 nm to about 2000 nm, for example about 920 nm to about 2000 nm, for example about 940 nm to about 2000 nm, for example about 960 nm to about 2000 nm, for example about 980 nm to about 2000 nm, for example about 990 nm to about 2000 nm, for example about 1000 nm to about 2000 nm, for example about 1050 nm to about 2000 nm or for example about 1100 nm to about 2000 nm.

The compound represented by Chemical Formula 1 may exhibit good photoelectric conversion characteristics in the infrared (absorption) wavelength region and can therefore be effectively used in the infrared photoelectric conversion layer 31 of an infrared sensor. As an example, the energy bandgap of the compound represented by Chemical Formula 1 may be, for example, about 0.5 eV to about 2.0eV, and within the above range, about 0.6 eV to about 1.8 eV, about 0.7 eV to about 1.6 eV, about 0.8 eV to about 1.4 eV based on simulation results. As an example, the HOMO energy level of the compound represented by Chemical Formula 1 may be, for example, about 4.0 eV to about 5.8 eV, and within the above range, about 4.2 eV to about 5.6 eV, about 4.4 eV to about 5.4 eV, or about 4.5 eV to about 5.0 eV.

The compound represented by Chemical Formula 1 may be a compound having an asymmetric structure (e.g., a compound having an asymmetric molecular structure) based on introducing anthracene or tetracene into a structure of porphyrazine, phthalocyanine, or naphthalocyanine. The above structure can improve light absorption characteristics in the infrared absorption wavelength region. In some example embodiments, an infrared sensor 100 may have improved light absorption characteristics in the infrared absorption wavelength region (e.g., improved sensitivity in a low-illumination environment), and thus may exhibit improved photoelectric conversion performance and/or efficiency based on the infrared photoelectric conversion layer 31 of the infrared sensor 100 including the compound represented by Chemical Formula 1 (e.g., as a p-type semiconductor and/or as an n-type semiconductor). In some example embodiments, an infrared sensor 100 may be configured to photoelectrically convert incident light (e.g., incident light in the infrared wavelength region) with reduced power consumption and without compromising photoelectric conversion performance, based on the infrared photoelectric conversion layer 31 of the infrared sensor 100 including the compound represented by Chemical Formula 1 (e.g., as a p-type semiconductor and/or as an n-type semiconductor). In some example embodiments, the infrared photoelectric conversion layer 31 may include a p-type semiconductor and an n-type semiconductor, where the p-type semiconductor and an n-type semiconductor are each represented by Chemical Formula 1 and are different from each other.

The compound represented by Chemical Formula 1 may or may not contain a central metal (M), and the central metal may be a divalent to tetravalent metal, for example Zn, Mn, Sn, Co, Ru. Ni, V, Si, or Ge. In some example embodiments, the central metal may be a transition metal.

In some example embodiments, in Chemical Formula 1, a pair of R¹¹ and R¹², a pair of R²¹ and R²², and a pair of R³¹ and R³² may each independently be linked to each other to form a substituted benzene ring or a substituted naphthalene ring, and the substituted benzene ring or the substituted naphthalene ring may be substituted with a substituent selected from deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof. In some example embodiments, in Chemical Formula 1, at least one pair of a pair of R¹¹ and R¹², a pair of R²¹ and R²², or a pair of R³¹ and R³² may each independently be linked to each other to form a substituted benzene ring or a substituted naphthalene ring, and the substituted benzene ring or the substituted naphthalene ring may be substituted with a substituent selected from deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof.

In Chemical Formula 1, any one of R^{1a}, R^{1b}, R^{1d}, R^{1e}, R¹¹, R¹², R²¹, R²², R³¹, or R³² may be a C6 to C20 haloalkyl group, a C6 to C20 cyanoalkyl group, a C6 to C20 alkyl group, a hydroxy group, or a C6 to C20 alkoxy group, or a C3 to C22 alkylene glycol-derived group (*—O—[(CH₂)₂—O]ₙ—R, wherein R is a C1 to C20 alkyl group and n is an integer of 1 to 10). When these long-chain substituents are introduced, solubility of the compound in solvents is improved and the compound may be used in solution processes and thus may be included (or may more easily included) in a layer formed from a solution (e.g., an infrared photoelectric conversion layer 31).

The molecular weight of the compound represented by Chemical Formula 1 may be in the range of be less than or equal to about 900, for example less than or equal to about 890, less than or equal to about 880, less than or equal to about 870, less than or equal to about 860, or less than or equal to about 850. For example, the compound represented by Chemical Formula 1 may have a molecular weight of greater than or equal to about 500. Within the above range, the deposition temperature can be lowered and deposition stability can be improved, and thus the likelihood of process defects in an infrared photoelectric conversion layer 31 that includes the compound represented by Chemical Formula 1 may be reduced.

The compound represented by Chemical Formula 1 has good heat resistance, and thus may prevent, minimize, or reduce thermal decomposition during deposition, and thus may be repeatedly deposited, and thus the likelihood of process defects in the infrared sensor 100 may be reduced, minimized, or prevented based on including an infrared photoelectric conversion layer 31 that includes the compound represented by Chemical Formula 1. The compound represented by Chemical Formula 1 may be thermally or vacuum deposited and may be deposited, for example, by sublimation. For example, deposition by sublimation may be confirmed by thermogravimetric analysis (TGA), and at a thermogravimetric analysis at a pressure of less than or equal to about 10 Pa, a temperature at which a 5% weight loss relative to an initial weight may be less than or equal to about 500° C. For example, at a thermogravimetric analysis at a pressure of less than or equal to about 10 Pa, a temperature at which a 5% weight loss relative to an initial weight of the compound may be for example about 230° C. to about 500° C.

The compound represented by Chemical Formula 1 may have a permanent dipole moment of greater than or equal to about 1.2 Debye, for example greater than or equal to about 1.3 Debye, greater than or equal to about 1.4 Debye, greater than or equal to about 1.5 Debye, greater than or equal to about 1.6 Debye, and less than or equal to about 10 Debye, for example less than or equal to about 9 Debye. The compound represented by Chemical Formula 1 having a permanent dipole moment within the above range can exhibit light absorption characteristics in a long wavelength region, and thus an infrared sensor 100 may have improved photoelectric conversion performance and/or efficiency (e.g., reduced power consumption without compromising photoelectric conversion performance) based on having an infrared photoelectric conversion layer 31 that includes the compound represented by Chemical Formula 1.

The compound represented by Chemical Formula 1 may have an aspect ratio of greater than about 2.0, greater than or equal to about 2.1, greater than or equal to about 2.2, or greater than or equal to about 2.3 and less than or equal to about 8.0,less than or equal to about 7.5, less than or equal to about 7.0, less than or equal to about 6.5, less than or equal to about 6.0, or less than or equal to about 5.5. When the aspect ratio is in the above range, the permanent dipole moment of the compound represented by Chemical Formula 1 can be adjusted to a desired range and thus can be adjusted to exhibit light absorption characteristics in a long wavelength region, and thus an infrared sensor 100 may have improved photoelectric conversion performance and/or efficiency (e.g., reduced power consumption without compromising photoelectric conversion performance) in a long wavelength region such as an infrared wavelength region based on having an infrared photoelectric conversion layer 31 that includes the compound represented by Chemical Formula 1.

An angle between a permanent dipole moment (PDM) direction and a z-axis of the compound represented by Chemical Formula 1 may be greater than or equal to about 30 degrees, for example greater than or equal to about 45 degrees, greater than or equal to about 50 degrees, greater than or equal to about 55 degrees, greater than or equal to about 60 degrees, greater than or equal to about 65 degrees, or greater than or equal to about 70 degrees. When the permanent dipole moment (PDM) direction and the z-axis have an angle within the above range, the longitudinal direction of the aspect ratio of the molecule and the direction of the permanent dipole moment can be designed in a direction that is the same, and thus the effect of stacking between molecules in a head-to-tail form may be maximized, and this structure can improve charge mobility when applied to devices and improve light absorption characteristics in the long wavelength region, and thus an infrared sensor 100 may have improved photoelectric conversion performance and/or efficiency (e.g., reduced power consumption without compromising photoelectric conversion performance) in a long wavelength region such as an infrared wavelength region based on having an infrared photoelectric conversion layer 31 that includes the compound represented by Chemical Formula 1.

Specific examples of the compound represented by Chemical Formula 1include compounds of Group 1.

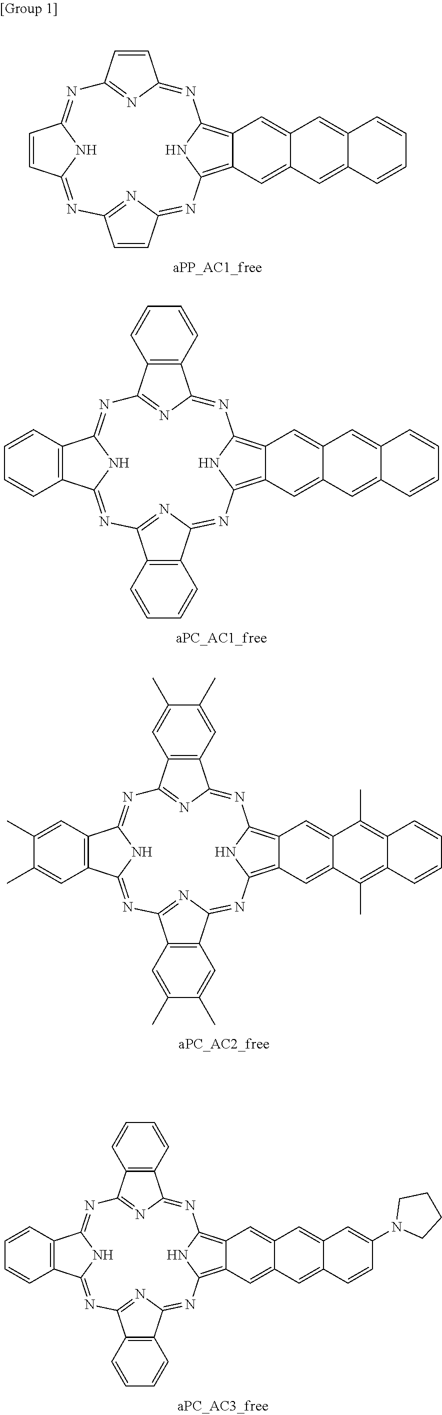 [SMILES: C1=Cc2nc1nc1ccc(nc3nc(nc4[nH]c(n2)c2cc5cc6ccccc6cc5cc42)C=C3)[nH]1 ; c1ccc2c(c1)-c1nc-2nc2[nH]c(nc3nc(nc4[nH]c(n1)c1ccccc41)-c1ccccc1-3)c1cc3cc4ccccc4cc3cc21 ; Cc1cc2c(cc1C)-c1nc-2nc2[nH]c(nc3nc(nc4[nH]c(n1)c1cc5c(C)c6ccccc6c(C)c5cc41)-c1cc(C)c(C)cc1-3)c1cc(C)c(C)cc21 ; c1ccc2c(c1)-c1nc-2nc2[nH]c(nc3nc(nc4[nH]c(n1)c1ccccc41)-c1ccccc1-3)c1cc3cc4cc(N5CCCC5)ccc4cc3cc21]

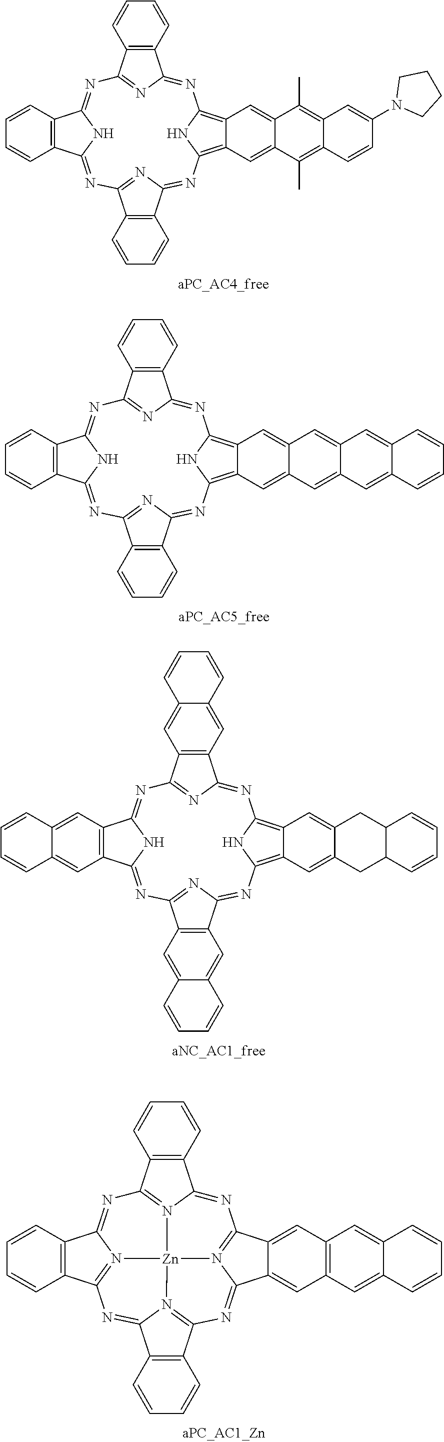

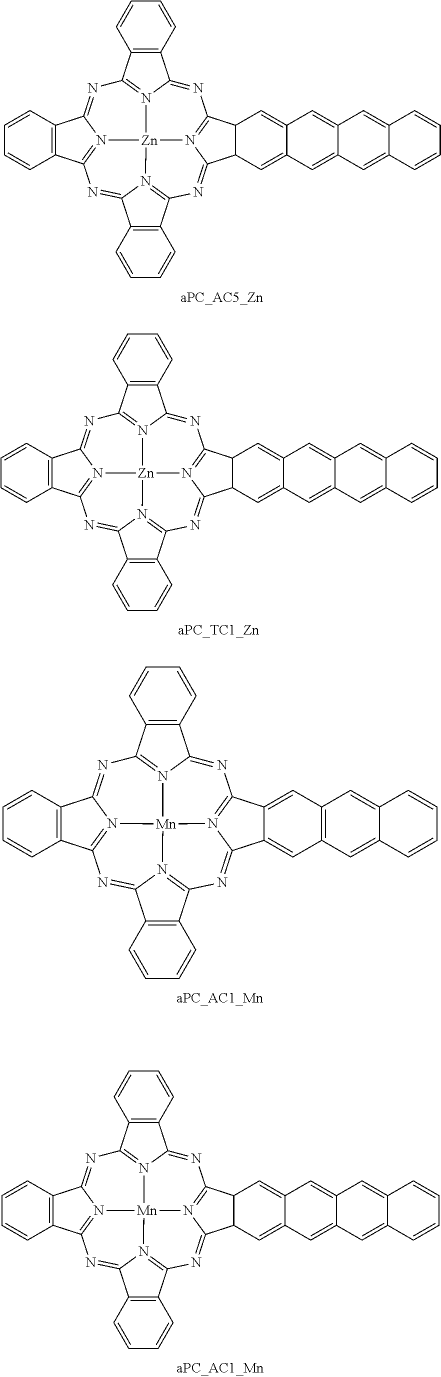

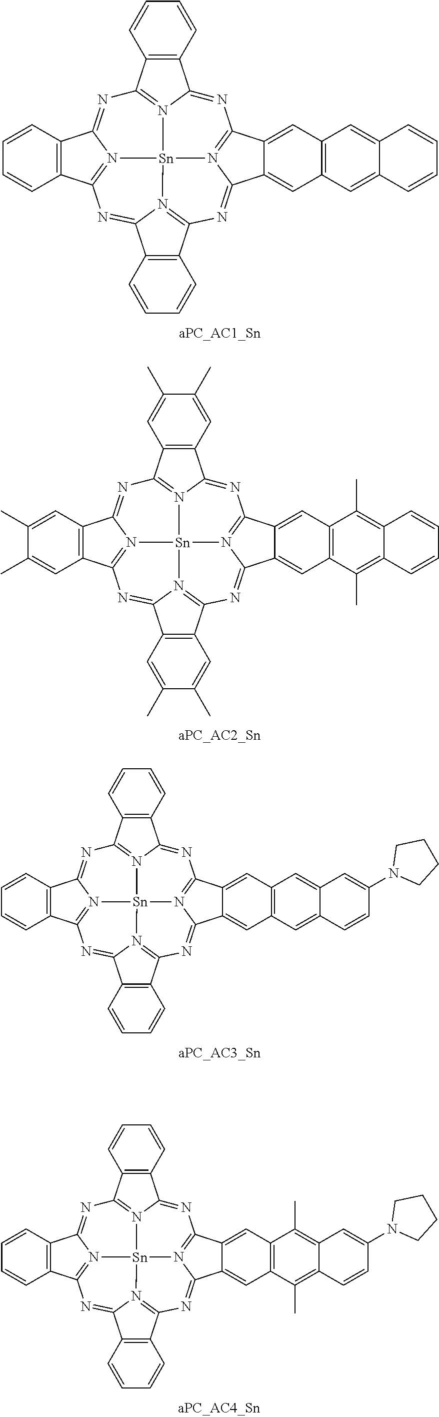

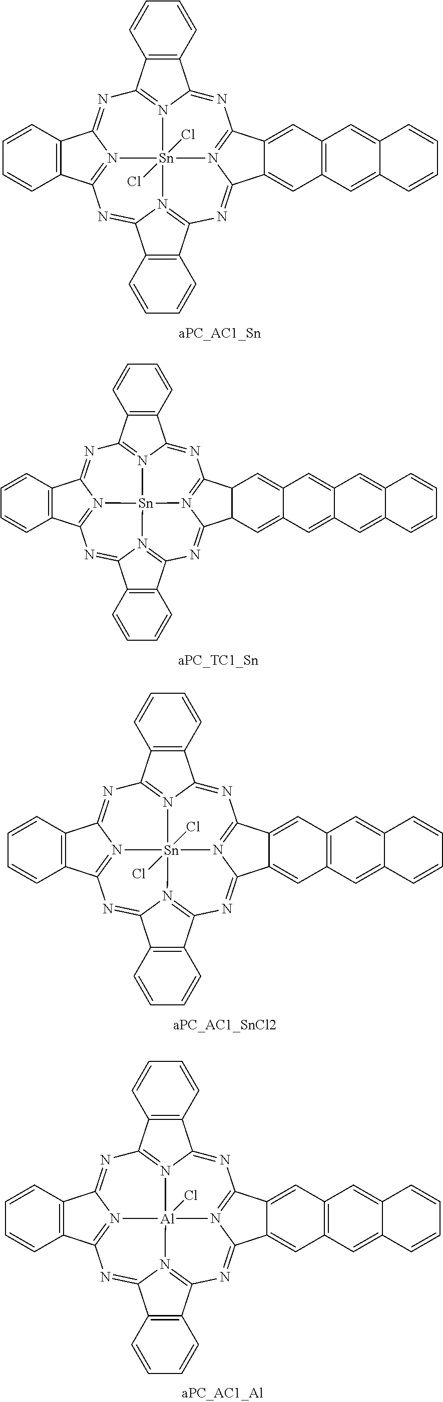

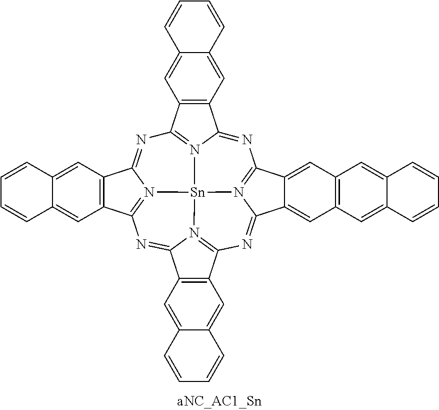 [SMILES: c1ccc2cc3c(cc2c1)C1=[N]2->[Sn]45<-[N]6=C(/N=C7/c8cc9cc%10ccccc%10cc9cc8C(=[N]->47)/N=C4/c7cc8ccccc8cc7C(=[N]->54)/N=C/32)c2cc3ccccc3cc2/C6=N/1]

The infrared photoelectric conversion layer 31 may have a thickness (e.g., in a depth direction perpendicular to an in-plane direction of the infrared photoelectric conversion layer 31) of about 30 nm to about 500 nm, and within the above range, about 50 nm to about 400 nm, about 80 nm to about 300 nm, about 100 nm to about 200 nm, or about 140 nm to about 160 nm.

The auxiliary layers 32 and 33 may be further included between the first electrode 10 and the infrared photoelectric conversion layer 31 and/or between the second electrode 20 and the infrared photoelectric conversion layer 31, respectively.

For example, the auxiliary layers 32 and 33 may be charge auxiliary layers, and efficiency may be increased by facilitating the movement of holes and electrons separated from the infrared photoelectric conversion layer 31. The auxiliary layers 32 and 33 may include at least one selected from a hole injecting layer (HIL) that facilitates hole injection, a hole transporting layer (HTL) that facilitates hole transport, an electron blocking layer (EBL) that blocks the movement of electrons, an electron injecting layer (EIL) that facilitates electron injection, an electron transporting layer (ETL) that facilitates the transport of electrons, and a hole blocking layer (HBL) that blocks the movement of holes.

As an example, the auxiliary layers 32 and 33 may be light absorption auxiliary layers, and may be disposed on and/or under the infrared photoelectric conversion layer 31 to increase a quantity of light absorbed by the infrared photoelectric conversion layer 31 and thereby to improve light absorption properties. For example, one of the auxiliary layers 32 and 33 may include fullerene or a fullerene derivative.

The auxiliary layers 32 and 33 may include, for example, an organic material, an inorganic material, or an organic-inorganic material.

For example, at least one of the auxiliary layers 32 and/or 33 may include a low molecular weight compound, for example, may include the compound represented by Chemical Formula 1.

For example, at least one of the auxiliary layers 32 and 33 may include a low molecular weight compound, for example, a carbazole-containing compound.

As an example, at least one of the auxiliary layers 32 and 33 may include a polymer.

As an example, at least one of the auxiliary layers 32 and/or 33 may include the aforementioned compound represented by Chemical Formula 1.

For example, at least one of the auxiliary layers 32 or 33 may include an inorganic material, for example, a lanthanide element such as ytterbium (Yb); calcium (Ca); potassium (K); barium (Ba); magnesium (Mg); lithium fluoride (LiF); or an alloy thereof.

For example, at least one of the auxiliary layers 32 or 33 may include fullerene or a fullerene derivative.

For example, one of the auxiliary layers 32 and 33 may include an inorganic material, and may include a metal oxide such as molybdenum oxide, tungsten oxide, or nickel oxide.

The auxiliary layers 32 and 33 may have each independently a thickness (e.g., in a depth direction perpendicular to an in-plane direction of the auxiliary layers 32 and/or 33) of about 1 nm to about 200 nm, within the range, about 5 nm to about 200nm, about 5 nm to about 180 nm, or about 5 nm to about 150 nm.

At least one of the auxiliary layers 32 and/or 33 may be omitted.

The infrared sensor 100 may further include an anti-reflection layer (not shown) on one surface of the first electrode 10 or the second electrode 20. The anti-reflection layer may be disposed at the side to which the light is incident to reduce a reflectance of the incident light, thereby further improving light absorption. For example, when light is incident to the first electrode 10, the anti-reflection layer may be disposed under the first electrode 10, and when light is incident to the second electrode 20, the anti-reflection layer may be disposed on the second electrode 20.

The anti-reflection layer may include, for example a material having a refractive index of about 1.6 to about 2.5, and may include for example at least one of metal oxide, metal sulfide, or an organic material having a refractive index within the ranges. The anti-reflection layer may include, for example a metal oxide such as aluminum-containing oxide, molybdenum-containing oxide, tungsten-containing oxide, vanadium-containing oxide, rhenium-containing oxide, niobium-containing oxide, tantalum-containing oxide, titanium-containing oxide, nickel-containing oxide, copper-containing oxide, cobalt-containing oxide, manganese-containing oxide, chromium-containing oxide, tellurium-containing oxide, or any combination thereof; metal sulfide such as zinc sulfide; or an organic material such as an amine derivative, but is not limited thereto.

The infrared sensor 100 may further include an encapsulation film (not shown) on one surface of the first electrode 10 or the second electrode 20.

The infrared sensor 100 may further include an optical auxiliary layer (not shown) on one surface of the first electrode 10 or the second electrode 20. The optical auxiliary layer may selectively transmit light in a particular (or, alternatively, predetermined) wavelength region among incident light and may reflect and/or absorb light in a wavelength region other than that. That is, the optical auxiliary layer may be a selective transmission layer, for example, may be a semi-transmissive layer.

The optical auxiliary layer may include, for example, a first optical auxiliary layer and a second optical auxiliary layer having different refractive indices. The first optical auxiliary layer may be for example a high refractive index layer and the second optical auxiliary layer may be for example a low refractive index layer. The refractive index (at about 800 nm to about 1200 nm) of the high refractive index layer may be, for example, greater than or equal to about 1.55 or about 1.55 to about 1.90, and the refractive index (at about 800 nm to about 1200 nm) of the low refractive index layer may be, for example, less than or equal to about 1.55 or greater than or equal to about 1.20 and less than about 1.55. For example, the first optical functional layer may be an aluminum oxide, an organic buffer material, an inorganic buffer material, or any combination thereof, and the second optical functional layer may be a silicon oxide, a silicon nitride, a silicon oxynitride, or any combination thereof, but are limited thereto.

In the infrared sensor 100, when light is incident from the side of the first electrode 10 or the second electrode 20 and the infrared photoelectric conversion layer 31 absorbs light in the infrared wavelength region, excitons may be generated therein. The generated excitons are separated into holes and electrons in the infrared photoelectric conversion layer 31. The separated holes may move towards the anode which is one of the first electrode 10 or the second electrode 20, and the separated electrons move towards the cathode which is the other of the first electrode 10 or the second electrode 20, and thus an electrical signal may be obtained.

For example, when the infrared sensor 100 includes a reflective electrode and a (semi) light-transmitting layer as the first electrode 10 and the second electrode 20, a microcavity structure may be formed. Due to the microcavity structure, incident light may be repeatedly reflected between the reflective layer and the (semi) light-transmitting layer which are separated by a particular (or, alternatively, predetermined) optical path length to enhance light having a particular (or, alternatively, predetermined) wavelength spectrum. For example, light having a particular (or, alternatively, predetermined) wavelength spectrum among the incident light may be modified by repeatedly reflecting between the reflective layer and the (semi) light-transmitting layer, and among the modified light, light of a wavelength spectrum corresponding to a resonance wavelength of the microcavity may be enhanced to exhibit amplified photoelectric conversion characteristics in a narrow wavelength region.

Due to this microcavity structure, an absorption spectrum of the infrared photoelectric conversion layer 31 may further include a sub absorption spectrum in addition to the aforementioned main absorption spectrum. The sub absorption spectrum may be located in a longer wavelength region than the main absorption spectrum and a peak wavelength of the sub absorption spectrum may be for example greater than or equal to about 1000 nm, greater than or equal to about 1050 nm, greater than or equal to about 1100 nm, greater than or equal to about 1150 nm, greater than or equal to about 1200 nm, for example about 1000 nm to about 3000 nm, about 1050 nm to about 3000 nm, about 1100 nm to about 3000 nm, about 1150 nm to about 3000 nm, or about 1200 nm to about 3000 nm.

The infrared sensor 100 may be applied to various fields for sensing light in the infrared wavelength region, for example, an image sensor for improving sensitivity in a low light environment, a sensor for increasing detection capability of 3D images by broadening the dynamic range for detailed black and white contrast, a security sensor, a vehicle sensor, a biometric sensor, or the like, and the biometric sensor may be, for example, an iris sensor; a distance sensor; a fingerprint sensor; a biosignal sensor such as a PPG sensor; or a living body imaging sensor such as a blood vessel imaging sensor, but is not limited thereto. The infrared sensor may be applied to, for example, a CMOS infrared sensor or a CMOS image sensor.

The CMOS infrared sensor may include a plurality of pixels, and at least some of the plurality of pixels may include the aforementioned infrared sensor 100. The CMOS infrared sensor may include a plurality of infrared sensors 100 arranged in an array form along a row and/or column on a semiconductor substrate.

While some example embodiments are described herein wherein the compound represented by Chemical Formula 1 is included in the infrared photoelectric conversion layer 31 of infrared sensor 100, an auxiliary layer 32, an auxiliary layer 33, or any combination thereof, it will be understood that example embodiments are not limited thereto. In some example embodiments, the compound represented by Chemical Formula 1 may be provided independently of any infrared sensor and/or layer. In some example embodiments, the compound represented by Chemical Formula 1 may be provided as an isolated compound and/or composition of matter. The compound represented by Chemical Formula 1 may be isolated as a solid composition, a liquid composition, or the like. In some example embodiments, the compound represented by Chemical Formula 1 may be provided in a solution and/or mixture of compositions. In some example embodiments, the compound represented by Chemical Formula 1 may be provided as a thin film (e.g., a thin film having a thickness of about 30 nm to about 200 nm).

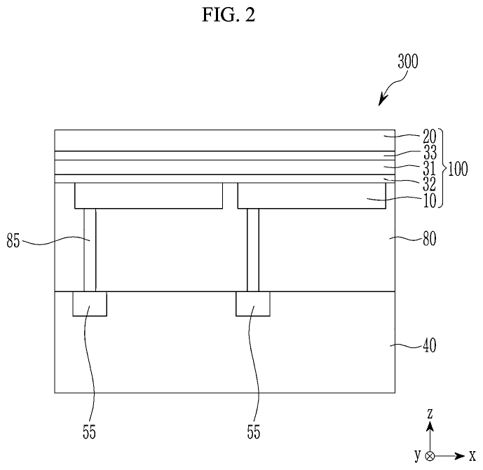

FIG. 2 is a cross-sectional view showing an example of a CMOS infrared sensor according to some example embodiments.

The CMOS infrared sensor 300 according to some example embodiments includes a semiconductor substrate 40, an insulating layer 80, and an infrared sensor 100.

The semiconductor substrate 40 may be a silicon substrate and is integrated with a transmission transistor (not shown) and a charge storage 55. The charge storage 55 may be integrated in each pixel. The charge storage 55 is electrically connected to the infrared sensor 100 and information of the charge storage 55 may be transmitted by the transmission transistor.

A metal wire (not shown) and a pad (not shown) are formed on the semiconductor substrate 40. In order to decrease signal delay, the metal wire and pad may be made of a metal having low resistivity, for example, aluminum (Al), copper (Cu), silver (Ag), and/or alloys thereof, but is not limited thereto. However, example embodiments are not limited to the structure and the metal wire and pads may be disposed under the semiconductor substrate 40.

The insulating layer 80 is formed on the metal wire and the pad. The insulating layer 80 may be made of an inorganic insulating material such as a silicon oxide and/or a silicon nitride, or a low dielectric constant (low K) material such as SiC, SiCOH, SiCO, and SiOF. The insulating layer 80 has a trench 85 exposing the charge storage 55. The trench 85 may be filled with fillers.

The aforementioned infrared sensor 100 is formed on the insulating layer 80. The infrared sensor 100 may include a first electrode 10, a second electrode 20, an infrared photoelectric conversion layer 31, and optionally auxiliary layers 32 and 33 as described above.

Both the first electrode 10 and the second electrode 20 may be transparent electrodes, and the descriptions for the first electrode 10, the second electrode 20, the infrared photoelectric conversion layer 31, and the auxiliary layers 32 and 33 are the same as described above. The light in the infrared wavelength region of the light incident from the side of the second electrode 20 may be effectively absorbed by the infrared photoelectric conversion layer 31 to be photoelectrically converted.

Focusing lens (not shown) may be further formed on the infrared sensor 100. The focusing lens may control a direction of incident light and gather the light in one region. The focusing lens may have a shape of, for example, a cylinder or a hemisphere, but is not limited thereto.

The infrared sensor 100 or the CMOS infrared sensor 300 may be included in a combination sensor including a plurality of sensors having different functions.

At least one of a plurality of sensors having different functions may be a biometric sensor. The biometric sensor may be for example an iris sensor, a depth sensor, a fingerprint sensor, or a blood vessel distribution sensor, but is not limited thereto. For example, one of a plurality of sensors having different functions may be an iris sensor and the other one may be a depth sensor.

For example, a plurality of sensors having different functions may include a first infrared sensor configured to sense light having a first wavelength (λ₁) within an infrared wavelength region and a second infrared sensor configured to sense infrared light having a second wavelength (λ₂) within an infrared wavelength region.

The first wavelength (λ₁) and the second wavelength (λ₂) may differ from each other within the infrared wavelength region. For example, a difference between the first wavelength (λ₁) and the second wavelength (λ₂) may be greater than or equal to about 30 nm, within the range greater than or equal to about 50 nm, greater than or equal to about 70 nm, greater than or equal to about 80 nm, or greater than or equal to about 90 nm.

For example, one of the first wavelength (λ₁) or the second wavelength (λ₂) may be within a wavelength region of about 800 nm to about 1000 nm, and the other of the first wavelength (λ₁) and the second wavelength (λ₂) may be within a wavelength region of greater than about 1000 nm and less than or equal to about 1500 nm.

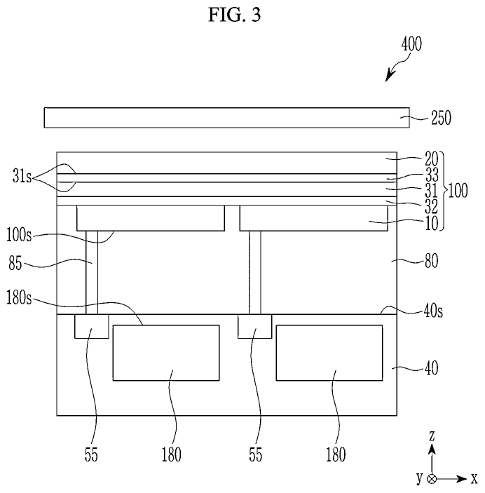

FIG. 3 is a cross-sectional view showing an example of a combination sensor according to some example embodiments.

The combination sensor 400 according to some example embodiments includes an optical filter 250; an infrared sensor 100; an insulating layer 80; and a semiconductor substrate 40 in which the photodiode 180 and the charge storage 55 are integrated. The infrared sensor 100 and the photodiode 180 are stacked along the depth direction (e.g., z direction) of the semiconductor substrate 40. Restated, the infrared sensor 100 and the photodiode 180 may be understood to be stacked together in a depth direction (e.g., z direction) that is perpendicular to a plane in which the infrared sensor 100 extends and/or an in-plane direction of the infrared sensor 100 (e.g., x and y directions) and/or is perpendicular to an upper surface 40s of the semiconductor substrate 40, opposing surfaces 100s, 180s of the infrared sensor 100 and the photodiode 180 and is further perpendicular to at least opposite surfaces 31s of the infrared photoelectric conversion layer 31, opposite surfaces of the first electrode 10, opposite surfaces of the second electrode 20 of the infrared sensor 100, or any combination thereof.

The optical filter 250 may be disposed on the front side of the combination sensor 400, and may selectively transmit light in the infrared wavelength region including the first wavelength (λ₁) and light in the infrared wavelength region including the second wavelength (λ₂) and may block and/or absorb other light. Herein, the other light may also include ultraviolet and visible light.

The infrared sensor 100 may be a first infrared sensor, and a detailed description is the same as described above.

The photodiode 180 may be a second infrared sensor and may be integrated in the semiconductor substrate 40. The semiconductor substrate 40 may be, for example, a silicon substrate, and a photodiode 180, a charge storage 55, and a transfer transistor (not shown) are integrated therein.

The infrared sensor 100 may be configured to detect (e.g., absorb and/or photoelectrically convert) incident light in a first wavelength spectrum, of the infrared wavelength spectrum, that includes the first wavelength (λ₁) of the infrared wavelength spectrum. The photodiode 180 may be configured to detect (e.g., absorb and/or photoelectrically convert) incident light in a second wavelength spectrum, of the infrared wavelength spectrum, that includes the second wavelength (λ₂) of the infrared wavelength spectrum. The second wavelength spectrum may be a shorter wavelength spectrum or a longer wavelength spectrum than the first wavelength spectrum. Restated, wavelengths in the second wavelength spectrum (e.g., the second wavelength (λ₂) of the infrared wavelength spectrum) may be shorter or longer wavelengths than wavelengths in the first wavelength spectrum (e.g., the first wavelength (λ₁) of the infrared wavelength spectrum). The first and second wavelength spectrums may partially overlap or may not overlap at all. In some example embodiments, a difference between closest wavelengths of non-overlapping first and second wavelength spectrums may be greater than or equal to about 30 nm, within the range greater than or equal to about 50 nm, greater than or equal to about 70 nm, greater than or equal to about 80 nm, or greater than or equal to about 90 nm. Said difference may be equal to or less than about 500 nm, equal to or less than about 400 nm, equal to or less than about 300 nm, equal to or less than about 200 nm, equal to or less than about 150 nm, equal to or less than about 100 nm, or equal to or less than about 95 nm.

The light entering the photodiode 180 is light that has passed the optical filter 250 and the infrared sensor 100 and may be light in a particular (or, alternatively, predetermined) region including the second wavelength (λ₂) of the infrared wavelength region. The infrared light in a particular (or, alternatively, predetermined) region including the first wavelength (λ₁) may be substantially all absorbed in the infrared photoelectric conversion layer 31 of the infrared sensor 100 and thus not reach the photodiode 180. Accordingly, a separate filter for wavelength selectivity of the light entering the photodiode 180 may not be needed. However, in case that the light in a particular (or, alternatively, predetermined) region including the first wavelength (λ₁) in the infrared wavelength region is not all absorbed in the infrared photoelectric conversion layer 31, a separate filter (not shown) may be disposed between the infrared sensor 100 and the photodiode 180. The first wavelength (λ₁) may be a peak absorption wavelength of (e.g., exhibited by) the first infrared sensor (e.g., infrared sensor 100), and the second wavelength (λ₂) may be a peak absorption wavelength of the second infrared sensor (e.g., photodiode).

The combination sensor 400 according to some example embodiments may not only work as a combination sensor by including two infrared sensors performing two different functions but also greatly improve sensitivity by stacking two sensors performing different functions in each pixel to double the number of pixels acting each infrared sensor without maintaining the same size.

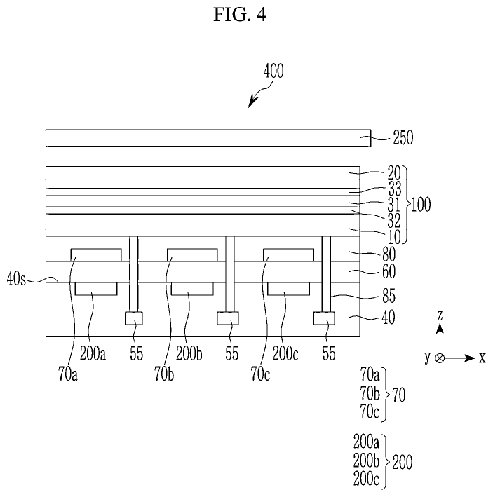

FIG. 4 is a cross-sectional view showing an example of a combination sensor according to some example embodiments.

Referring to FIG. 4, the combination sensor 400 according to some example embodiments includes an infrared sensor 100, a visible light sensor 200, and an optical filter 250.

As described above, the infrared sensor 100 includes a first electrode 10, a second electrode 20, an infrared photoelectric conversion layer 31, and optionally auxiliary layers 32 and 33. Details are the same as described above.

The visible light sensor 200 is a sensor configured to sense light in a visible light wavelength region, and may be a photodiode integrated in the semiconductor substrate 40. The visible light sensor 200 may be integrated in the semiconductor substrate 40 and may include a blue sensor 200a configured to sense light in a blue wavelength region, a green sensor 200b configured to sense light in a green wavelength region, and a red sensor 200c configured to sense light in a red wavelength region. As shown in FIG. 4, each of the blue sensor 200a, the green sensor 200b, and the red sensor 200c may be a photodiode that is integrated in the semiconductor substrate 40, such that the blue sensor 200a, the green sensor 200b, and the red sensor 200c are located within a volume space defined by outer surfaces (e.g., outermost surfaces, including for example the upper surface 40s) of the semiconductor substrate 40 and may be partially or completely enclosed within an interior of the semiconductor substrate 40. The blue sensor 200a may be integrated in the blue pixel, the green sensor 200b may be integrated in the green pixel, and the red sensor 200c may be integrated in the red pixel.

The semiconductor substrate 40 may be, for example, a silicon substrate, and a visible light sensor 200, a charge storage 55, and a transfer transistor (not shown) are integrated therein. The visible light sensor 200 may sense light in the visible light wavelength region that has passed through the optical filter 250, the infrared sensor 100, and the color filter layer 70, and the sensed information may be transmitted by the transmission transistor. The charge storage 55 is electrically connected to the infrared sensor 100.

A metal wire (not shown) and a pad (not shown) are formed on the semiconductor substrate 40. In order to decrease signal delay, the metal wire and pad may be made of a metal having low resistivity, for example, aluminum (Al), copper (Cu), silver (Ag), and alloys thereof, but is not limited thereto. However, the example embodiments are not limited to the structure and the metal wire and pads may be disposed under the blue sensor 200a, the green sensor 200b, and the red sensor 200c.

The lower insulating layer 60 is formed on the semiconductor substrate 40. The lower insulating layer 60 may be made of an inorganic insulating material such as a silicon oxide and/or a silicon nitride, or a low dielectric constant (low K) material such as SiC, SiCOH, SiCO, and/or SiOF.

The color filter layer 70 is formed on the lower insulating layer 60. The color filter layer 70 may include a blue filter 70a configured to selectively transmit light in the blue wavelength region, a green filter 70b configured to selectively transmit light in a green wavelength region, and a red filter 70c configured to selectively transmit light in the red wavelength region. The blue filter 70a, the green filter 70b, and the red filter 70c are each overlapped with the blue sensor 200a, the green sensor 200b, and the red sensor 200c, respectively, in a depth direction (e.g., z direction) that is perpendicular to an in-plane direction of the semiconductor substrate 40. The blue filter 70a may selectively transmit light in a blue wavelength region, the green filter 70b may selectively transmit light in a green wavelength region, and the red filter 70c may selectively transmit light in the red wavelength region. The transmitted light of the blue wavelength region may flow into the blue sensor 200a, the transmitted light of a green wavelength region may flow into the green sensor 200b, and the transmitted light of the red wavelength region may flow into the red sensor 200c. However, the present inventive concepts are not limited thereto, but at least one of the blue filter 70a, the green filter 70b, and the red filter 70c may be replaced with a yellow filter, a cyan filter, or a magenta filter. Herein, the color filter layer 70 is disposed between the infrared sensor 100 and the visible light sensor 200 but not limited thereto and may be disposed on the infrared sensor 100. For example, the upper insulating layer 80 and color filter layer 70 may be between the infrared sensor 100 and the optical filter 250.

An upper insulating layer 80 is formed on the color filter layer 70. The upper insulating layer 80 may be for example a planarization layer. The lower insulating layer 60 and the upper insulating layer 80 may have has a trench 85 exposing the charge storage 55. The trench 85 may be filled with fillers. At least one of the lower insulating layer 60 or the upper insulating layer 80 may be omitted.

The optical filter 250 is disposed on the visible light sensor 200 and the infrared sensor 100 and specifically, on the whole surface of the visible light sensor 200 and the infrared sensor 100. The optical filter 250 may selectively transmit light of a wavelength sensed in the visible light sensor 200 and light of a wavelength sensed in the infrared sensor 100 but reflect or absorb and thus block light of the other wavelengths.

Focusing lens (not shown) may be further formed on the upper or lower surface of the optical filter 250. The focusing lens may control a direction of incident light and gather the light in one region. The focusing lens may have a shape of, for example, a cylinder or a hemisphere, but is not limited thereto.

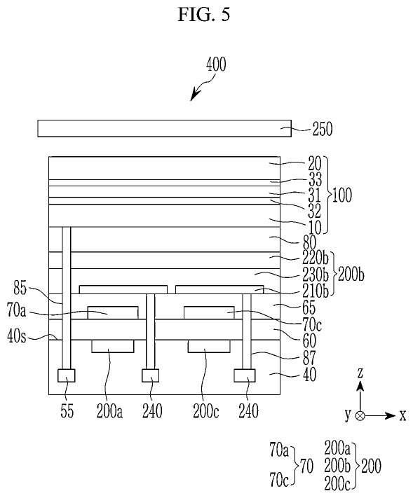

FIG. 5 is a cross-sectional view showing an example of a combination sensor according to some example embodiments.

The combination sensor 400 according to some example embodiments includes a semiconductor substrate 40, a color filter layer 70, an infrared sensor 100, a visible light sensor 200, and an optical filter 250, as in at least some of the aforementioned example embodiments.

The infrared sensor 100 includes a first electrode 10, a second electrode 20, an infrared photoelectric conversion layer 31, and optionally auxiliary layers 32 and 33, and details thereof are the same as described above.

The visible light sensor 200 may be a combination of a photodiode integrated in the semiconductor substrate 40 and a visible light photoelectric conversion device disposed on the semiconductor substrate 40.

In the semiconductor substrate 40, a blue sensor 200a, a red sensor 200c, charge storages 55 and 240, and a transfer transistor (not shown) are integrated. The blue sensor 200a and the red sensor 200c are photodiodes and are disposed to be spaced apart in the plane direction (e.g., xy direction) of the semiconductor substrate 40. The blue sensor 200a is integrated in the blue pixel and the red sensor 200c is integrated in the red pixel.

A lower insulating layer 60 and a color filter layer 70 are formed on the semiconductor substrate 40. The color filter layer 70 includes a blue filter 70a overlapped with the blue sensor 200a (e.g., overlapped in a depth direction perpendicular to the upper surface 40s of the semiconductor substrate 40) and a red filter 70c overlapped with the red sensor 200c (e.g., overlapped in a depth direction perpendicular to the upper surface 40s of the semiconductor substrate 40).

An intermediate insulating layer 65 is formed on the color filter layer 70. The lower insulating layer 60 and the intermediate insulating layer 65 may have trenches 85 and 87 exposing the charge storages 55 and 240. The intermediate insulating layer 65 may be made of an inorganic insulating material such as a silicon oxide and/or a silicon nitride, or a low dielectric constant (low K) material such as SiC, SiCOH, SiCO, and/or SiOF. The trenches 85 and 87 may be filled with filler materials. At least one of the lower insulating layer 60 and the intermediate insulating layer 65 may be omitted.

A green sensor 200b is formed on the intermediate insulating layer 65. The green sensor 200b may be a visible light photoelectric conversion device and formed on the whole surface of the semiconductor substrate 40. The green sensor 200b includes a lower electrode 210b and an upper electrode 220b facing each other and a green photoelectric conversion layer 230b disposed between the lower electrode 210b and the upper electrode 220b. Either one of the lower electrode 210b and the upper electrode 220b is an anode, and the other one is a cathode.

Both of the lower electrode 210b and the upper electrode 220b may be light-transmitting electrodes. The light-transmitting electrode may be for example made of a transparent conductor such as indium tin oxide (ITO), indium zinc oxide (IZO) or may be a metal thin film formed with a thin thickness of several nanometers to several tens of nanometer thickness or a single layer or multiple layers of metal thin film formed with a thin thickness of several nanometers to tens of nanometer thickness and doped with metal oxide.

The green photoelectric conversion layer 230b may selectively absorb light in a green wavelength region and allow light from wavelength regions other than the green wavelength region, that is, the blue wavelength region and the red wavelength region, to pass through. The green photoelectric conversion layer 230b may be formed on the whole surface of the combination sensor 400. As a result, the green photoelectric conversion layer 230b selectively absorbs light in a green wavelength region from the whole surface of the combination sensor 400 and increases light areas, thus having high absorption efficiency.

The green photoelectric conversion layer 230b selectively absorbs light in a green wavelength region, forms excitons, and separates the excitons into holes and electrons. The separated holes move towards the anode which is one of the lower electrode 210b and the upper electrode 220b, while the separated electrons move toward the cathode which is the other of the lower electrode 210b and the upper electrode 220b, and thus a photoelectric conversion effect may be obtained. The separated electrons and/or holes may be collected in the charge storage 240.

An auxiliary layer (not shown) may be further included between the lower electrode 210b and the green photoelectric conversion layer 230b and/or between the upper electrode 220b and the green photoelectric conversion layer 230b. The auxiliary layer may be a charge auxiliary layer, a light absorption auxiliary layer, or any combination thereof, but is not limited thereto.

Herein, an example structure in which the blue sensor 200a and the red sensor 200c are photodiodes and the green sensor 200b is a photoelectric conversion device is described, but example embodiments are not limited thereto. The blue sensor 200a and the green sensor 200b may be photodiodes and the red sensor 200c may be a photoelectric conversion device or the green sensor 200b and the red sensor 200c may be photodiodes and the blue sensor 200a may be a photoelectric conversion device.

On the green sensor 200b, an upper insulating layer 80 is formed, and on the upper insulating layer 80, the infrared sensor 100 and the optical filter 250 are disposed. The infrared sensor 100 and the optical filter 250 are the same as described above.

In FIG. 5, a structure in which the infrared sensor 100 is disposed on the green sensor 200b, which is one of the visible light photoelectric conversion devices, is illustrated, but example embodiments are not limited thereto, and the green sensor 200b may be disposed on the infrared sensor 100.

The combination sensor 400 according to some example embodiments may include an infrared sensor 100 and a visible light sensor 200 stacked along the depth direction (e.g., z direction) of the semiconductor substrate 40 and the visible light sensor 200 also has a structure in which a photodiode and a visible light photoelectric conversion device are stacked, thereby further reducing an area of the combination sensor and thus implementing miniaturization of the combination sensor.

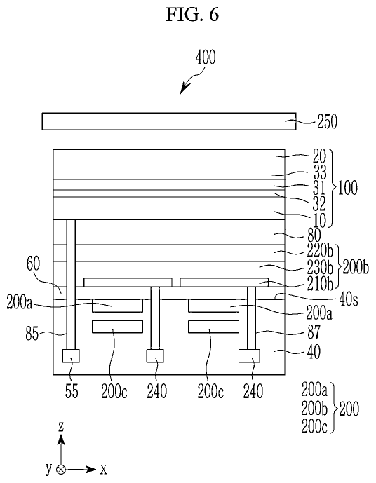

FIG. 6 is a cross-sectional view schematically showing an example of a combination sensor according to some example embodiments.

Referring to FIG. 6, the combination sensor 400 according to some example embodiments includes a semiconductor substrate 40, an infrared sensor 100, a visible light sensor 200, and an optical filter 250 as in at least some of the aforementioned example embodiments.

The infrared sensor 100 includes a first electrode 10, a second electrode 20, an infrared photoelectric conversion layer 31, and optionally auxiliary layers 32 and 33, and details are the same as described above.

The visible light sensor 200 include the blue sensor 200a and the red sensor 200c integrated in the semiconductor substrate 40 and a green sensor 200b disposed on the semiconductor substrate 40, wherein the blue sensor 200a and the red sensor 200c may be photodiodes, and the green sensor 200b may be a visible light photoelectric conversion device. The green sensor 200b includes the lower electrode 210b, the green photoelectric conversion layer 230b, and the upper electrode 220b.

However, in the combination sensor 400 according to some example embodiments, the blue sensor 200a and the red sensor 200c integrated in the semiconductor substrate 40 are stacked along a depth direction (e.g., z direction) of the semiconductor substrate 40, where the depth direction may be perpendicular to an in-plane direction of the semiconductor substrate 40 (e.g., perpendicular to the upper surface 40s). The blue sensor 200a and the red sensor 200c may selectively absorb and sense light in each wavelength region along the stacking depth from the upper surface 40s of the semiconductor substrate 40. In other words, the red sensor 200c absorbing red light in the long wavelength region may be disposed deeper than the blue sensor 200a absorbing blue light in the short wavelength region from the surface of the semiconductor substrate 40. In this way, since absorption wavelengths are separated along the stacking depth from the upper surface 40s of the semiconductor substrate 40, the color filter layer 70 for separating the absorption wavelengths may be omitted.

Herein, the blue sensor 200a and the red sensor 200c are, for example, each illustrated to be photodiodes, while the green sensor 200b is to be a photoelectric conversion device, but the present inventive concepts are not limited thereto, and the blue sensor 200a and the green sensor 200b may be photodiodes, while the red sensor 200c may be a photoelectric conversion device, or the green sensor 200b and the red sensor 200c may be photodiodes, while the blue sensor 200a may be a photoelectric conversion device.

FIG. 6 exhibits a structure that the infrared sensor 100 is disposed on the green sensor 200b, one of the visible light photoelectric conversion devices, but the present inventive concepts are not limited thereto, and the green sensor 200b may be disposed on the infrared sensor 100.

The combination sensor 400 according to some example embodiments is a combination sensor equipped with the infrared sensor 100 and the visible light sensor 200 which are stacked each other, the visible light sensor 200 is also equipped with a photodiode and a visible light photoelectric conversion device which are stacked on each other, and the photodiode also has a stacked structure, resultantly reducing the area of the combination sensor and thus realizing down-sizing of the combination sensor. In addition, the combination sensor 400 according to some example embodiments may include no separate color filter layer and thereby may simplify the structure and the process.

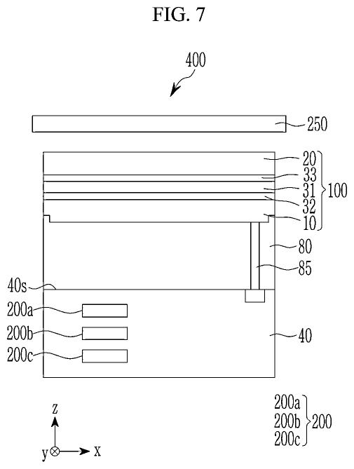

FIG. 7 is a cross-sectional view schematically showing an example of a combination sensor according to some example embodiments.

Referring to FIG. 7, the combination sensor 400 according to some example embodiments, as in at least some of the aforementioned example embodiments, includes the semiconductor substrate 40, the infrared sensor 100, the visible light sensor 200, and the optical filter 250.

The infrared sensor 100, as described above, includes the first electrode 10, the second electrode 20, the infrared photoelectric conversion layer 31, and optionally, the auxiliary layers 32 and 33, and details thereof are the same as described above.

The visible light sensor 200 includes the blue sensor 200a, the green sensor 200b, and the red sensor 200c integrated in the semiconductor substrate 40. The blue sensor 200a, the green sensor 200b, and the red sensor 200c are stacked in the semiconductor substrate 40 along the depth direction (e.g., z direction) of the semiconductor substrate 40 (which may be a direction perpendicular to an in-plane direction of the semiconductor substrate 40 and/or a direction perpendicular to the upper surface 40s of the semiconductor substrate 40). The blue sensor 200a, the green sensor 200b, and the red sensor 200c may have separate absorption wavelengths along the stacking depth and thus may selectively absorb different wavelength regions of incident light based on depth from the upper surface 40s, and accordingly, the color filter layer 70 may be omitted. Between the semiconductor substrate 40 and the infrared sensor 100, the insulating layer 80 may be formed, and the insulating layer 60 has the trench 85. The semiconductor substrate 40 includes the charge storage 55 connected to the infrared sensor 100.

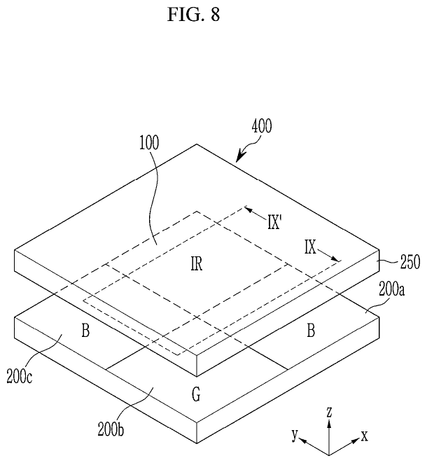

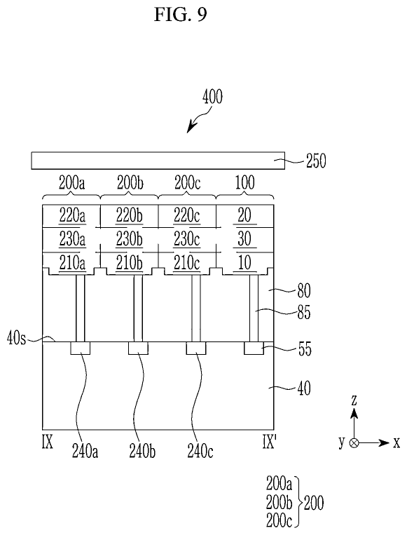

FIG. 8 is a perspective view schematically showing an example of a combination sensor according to some example embodiments and FIG. 9 is a cross-sectional view schematically showing an example of the combination sensor of FIG. 8 along view line IX-IX′ in FIG. 8 according to some example embodiments.

Referring to FIGS. 8 and 9, the combination sensor 400 according to some example embodiments, as in at least some of the aforementioned example embodiments, includes the semiconductor substrate 40; the infrared sensor 100; the visible light sensor 200; the insulating layer 80; and the optical filter 250. The visible light sensor 200 includes the blue sensor 200a, the green sensor 200b, and the red sensor 200c.

The infrared sensor 100, the blue sensor 200a, the green sensor 200b, and the red sensor 200c may be aligned side by side along (e.g., parallel with) an in-plane direction (e.g., xy direction) of the semiconductor substrate 40 and respectively connected, via respective trenches 85, to the charge storages 55, 240a, 240b, 240c integrated in the semiconductor substrate 40. Accordingly, as shown in at least FIGS. 8 and 9, the infrared sensor 100 may be arranged in parallel with the visible light sensor 200 along an in-plane direction of the semiconductor substrate 40.

The blue sensor 200a, the green sensor 200b, and the red sensor 200c may each be a visible light photoelectric conversion device.

The infrared sensor 100 includes a first electrode 10, a second electrode 20, an infrared photoelectric conversion layer 31, and optionally auxiliary layers (not shown), and details are the same as described above.

The blue sensor 200a includes a lower electrode 210a, a blue photoelectric conversion layer 230a, and an upper electrode 220a. The green sensor 200b includes a lower electrode 210b, a green photoelectric conversion layer 230b, and an upper electrode 220b. The red sensor 200c includes a lower electrode 210c, a red photoelectric conversion layer 230c, and an upper electrode 220c. The blue photoelectric conversion layer 230a may photoelectrically convert by selectively absorbing light in the blue wavelength region, the green photoelectric conversion layer 230b may photoelectrically convert by selectively absorbing light in the green wavelength region, and the red photoelectric conversion layer 230c may photoelectrically convert by selectively absorbing light in a red wavelength region.

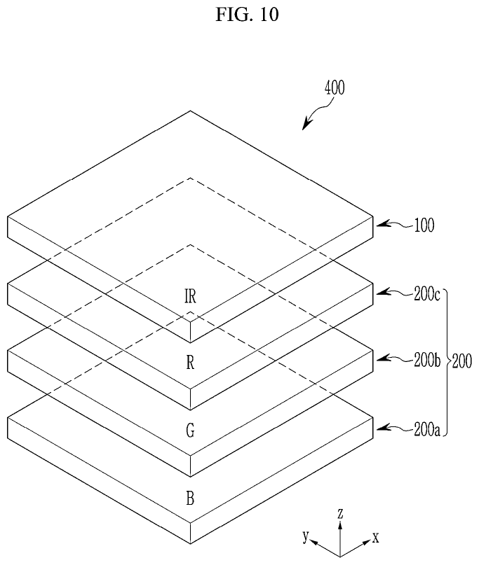

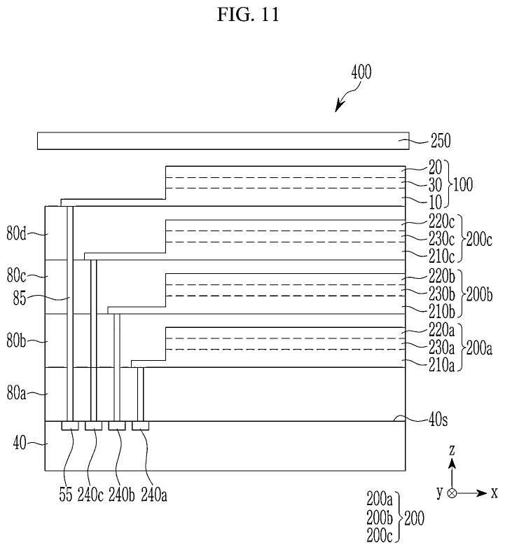

FIG. 10 is a perspective view schematically showing an example of a combination sensor according to some example embodiments and FIG. 11 is a cross-sectional view schematically showing an example of the combination sensor of FIG. 10 according to some example embodiments.

Referring to FIGS. 10 and 11, the combination sensor 400 according to some example embodiments includes a semiconductor substrate 40; infrared sensor 100; a visible light sensor 200; and an optical filter 250. The visible light sensor 200 includes a blue sensor 200a, a green sensor 200b, and a red sensor 200c.

The infrared sensor 100, the blue sensor 200a, the green sensor 200b, and the red sensor 200c may be stacked along the depth direction (e.g., z direction) of the semiconductor substrate 40, which may be a direction perpendicular to the in-plane direction of the semiconductor substrate 40 and/or a direction perpendicular to the upper surface 40s of the semiconductor substrate 40, and electrically connected to each charge storage 55, 240a, 240b, and 240c integrated in the semiconductor substrate 40. Accordingly, as shown in FIGS. 10 and 11, the infrared sensor 100 may be stacked with the visible light sensor 200 along the depth direction, which may be a direction perpendicular to the in-plane direction of the semiconductor substrate 40 and/or a direction perpendicular to the upper surface 40s of the semiconductor substrate 40.

The infrared sensor 100 includes a first electrode 10, a second electrode 20, an infrared photoelectric conversion layer 31, and optionally auxiliary layers (not shown), and details are the same as described above.

The blue sensor 200a includes a lower electrode 210a, a blue photoelectric conversion layer 230a, and an upper electrode 220a. The green sensor 200b includes a lower electrode 210b, a green photoelectric conversion layer 230b, and an upper electrode 220b. The red sensor 200c includes a lower electrode 210c, a red photoelectric conversion layer 230c, and an upper electrode 220c.

Each insulating layer 80a, 80b, 80c, and 80d may be disposed between the semiconductor substrate 40 and the blue sensor 200a, between the blue sensor 200a and the green sensor 200b, between the green sensor 200b and the red sensor 200c, and between the red sensor 200c and the infrared sensor 100. Each insulating layer 80a, 80b, 80c, and 80d may have a composition that is the same as the insulation layer 80 as described herein according to some example embodiments.

Some example embodiments, including the example embodiments shown in FIGS. 10 and 11, provide a structure that the infrared sensor 100, the blue sensor 200a, the green sensor 200b, and the red sensor 200c are sequentially stacked but example embodiments are not limited thereto, and the stacking order may be unlimitedly various.

The aforementioned infrared sensor 100, the CMOS infrared sensor 300, or the combination sensor 400 may be applied to various electronic devices, for example, a cell phone, a digital camera, a biometric device, a security device, auto electronic parts, and/or the like, but example embodiments are not limited thereto.

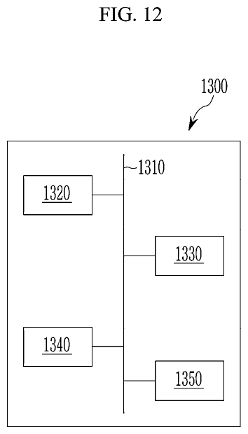

FIG. 12 is a schematic view of an electronic device according to some example embodiments.

Referring to FIG. 12, an electronic device 1300 includes a processor 1320, a memory 1330, a sensor 1340, and a display device 1350 electrically connected through a bus 1310. The sensor 1340 may be the aforementioned infrared sensor 100, CMOS infrared sensor 300, combination sensor 400, or any combination thereof. The processor 1320 may perform a memory program and thus at least one function. The processor 1320 may additionally perform a memory program and thus display an image on the display device 1350. The processor 1320 may generate an output.

The processor 1320 may include processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processor 1320 may be configured to generate an output (e.g., an image to be displayed on a display interface) based on such processing. One or more of the processor 1320, memory 1330, sensor 1340, or display device 1350 may be included in, include, and/or implement one or more instances of processing circuitry such as hardware including logic circuits, a hardware/software combination such as a processor executing software; or any combination thereof. In some example embodiments, said one or more instances of processing circuitry may include, but are not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, any of the memories, memory units, or the like as described herein may include a non-transitory computer readable storage device, for example a solid state drive (SSD), storing a program of instructions, and the one or more instances of processing circuitry may be configured to execute the program of instructions to implement the functionality of some or all of any of the electronic device 1300, processor 1320, memory 1330, sensor 1340, display device 1350, or the like according to any of the example embodiments as described herein.

Hereinafter, some example embodiments are illustrated in more detail with reference to examples. However, the scope of the inventive concepts is not limited to these examples.

### Synthesis Example 1: Synthesis of aPC_AC1_Zn (Compound 3)

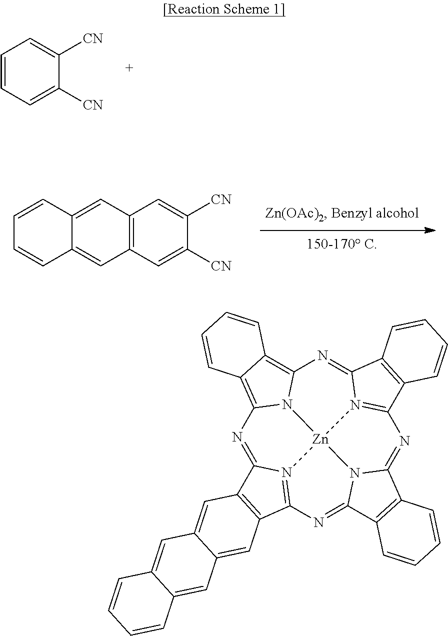

2,3-dicyanobenzene (128 mg, 1.0 mmol), 2,3-dicyanoanthracene (114 mg, 0.5 mmol), and benzyl alcohol (3 ml) are sequentially added to a pressure tube and then, completely dissolved by stirring and heating at 150° C. for 30 minutes to prepare a solution. To the solution, zinc (II) acetate (91.5 mg, 0.5 mmol) and 1,8-diazabicyclo (5.4.0)undec-7-ene (DBU) (3 drops) as a catalyst are added and then, stirred by heating at 170° C. for 12 hours. After cooling to room temperature (25° C.), methanol (10 ml) is added thereto and then, stirred for 30 minutes at the room temperature. Subsequently, precipitates produced therein are filtered with a filter and 5 times washed with methanol (30 ml) to obtain a crude product in a solid state. The crude product is treated through silica gel column (performed by gradually increasing a volume ratio of toluene:tetrahydrofuran (THF) from 100:0 to 0:100) to obtain aPC_AC1_Zn (Compound 3) (a yield: 14%).

MS (MALDI-TOF-MS, m/z) 676 (M+)

### Synthesis Example 2-1: Synthesis of aPC_AC1_Mn (Compound 5) I

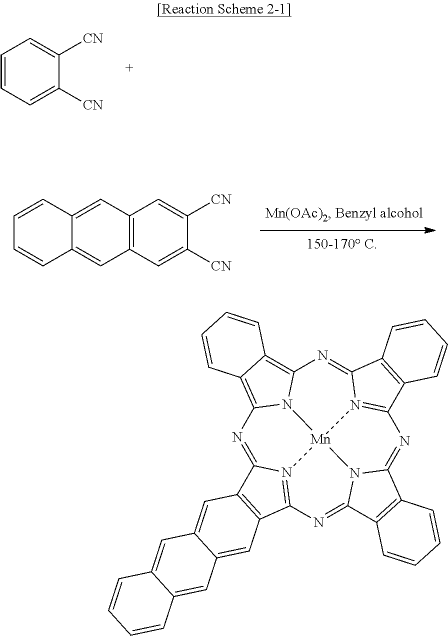

2,3-dicyanobenzene (128 mg, 1 mmol), 2,3-dicyanoanthracene (114 mg, 0.5 mmol), and benzylalcohol (3 ml) are sequentially added to a pressure tube and completely dissolved by stirring and heating at 150° C. for 30 minutes to prepare a solution. To the solution, manganese (II) acetate (86.5 mg, 0.5 mmol) and 1,8-diazabicyclo (5.4.0)undec-7-ene (DBU) (3 drops) as a catalyst are added and then, stirred by heating at 170° C. for 1 hour. After cooling to room temperature (25° C.), methanol (10 ml) is added thereto and then, stirred at the room temperature for 30 minutes. Then, precipitates produced therein are filtered with a filter and washed 5times with methanol (30 ml) and 5 times with tetrahydrofuran (30 ml) to obtain a crude product in a solid state. The crude product is dried and pulverized with a mortar and pestle and then, subject to Soxhlet extraction with 250 ml of toluene. Subsequently, a solid remaining there is dried to obtain aPC_AC1_Mn (Compound 5) in a solid state (a yield: 44%).

MS (MALDI-TOF-MS, m/z) 667 (M+)

### Synthesis Example 2-2: Synthesis of aPC_AC1_Mn (Compound 5) II

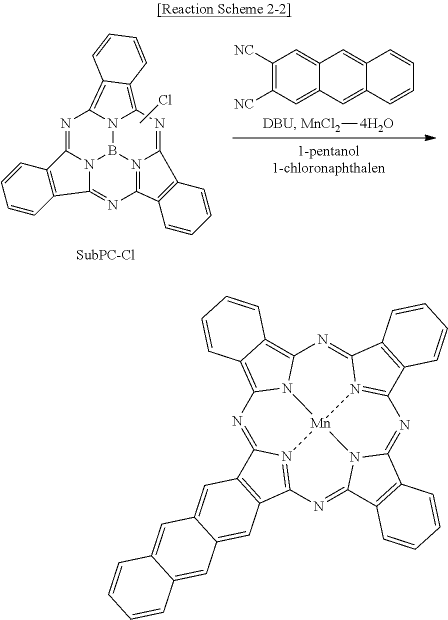

2,3-dicyanoanthacene (2.97 g, 1.6 eq) and DBU (0.87 g, 0.7 eq) as a catalyst are dissolved in 1-pentanol/1-chloronaphthalene (in a volume ratio of 3:1) (594 mL, 170 v/w) and then, heated to 130° C. to prepare a first solution. To the first solution, a solution prepared by dissolving SubPc-Cl (3.5 g, 1 eq) and MnCl2·4H2O (1.77 g, 1.1 eq) in 594 mL of 1-pentanol/1-chloronaphthalene (in a volume ratio of 3:1) is slowly added in a dropwise fashion. The obtained mixture is stirred at 130° C. to proceed a reaction overnight. After checking that SubPc-Cl disappears through a thin layer chromatography (TLC) analysis (ethylacetate (EA):hexane=1:3 in a volume ratio), the reaction solution is cooled to room temperature. Subsequently, the reaction solution is slowly poured into 1.5 L of hexane and then, stirred for 30 minutes, and solids produced therein are filtered. The solids are washed once with 100 mL of methanol and twice with 100 mL of hexane and then, dried to obtain 2.2 g of aPC_AC1_Mn (Compound 5) (a yield: 37%).

MS (MALDI-TOF-MS, m/z) 667 (M+)

### Synthesis Example 3: Synthesis of aPC_AC1_Sn (Compound 7)

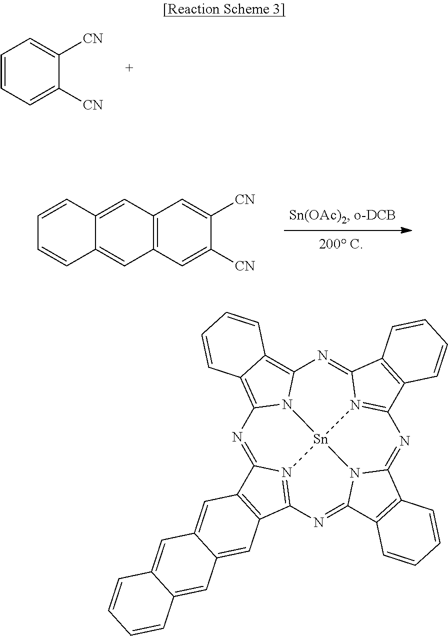

2,3-dicyanobenzene, 320 mg, 2.5 mmol), 2,3-dicyanoanthracene (228 mg, 1.0 mmol), and 1,2-dichlorobenzene (3 ml) are sequentially added to a pressure tube and then, completely dissolved by stirring and heating at 170° C. for 30 minutes to prepare a solution. To the solution, tin (II) acetate (236 mg, 1.0 mmol) is added and then, stirred by heating at 200° C. for 12 hours. After cooling to room temperature (25° C.), hexane (15 ml) is added thereto and then, stirred at room temperature for 30 minutes. Then, precipitates produced therein are filtered with a filter, washed 5 times with hexane (30 ml) and 5 times with methanol (30 ml) to obtain a crude product in a solid state. The crude product is treated through silica gel column (performed by increasing a volume ratio of dichloromethane (DCM):MeOH from 100:0 to 80:20) to obtain aPC_AC1_Sn (Compound 7) (a yield: 11%).

MS (MALDI-TOF-MS, m/z) 732 (M+)

### Manufacturing of Infrared Sensors

### Example 1

On a glass substrate, ITO (10 nm), Ag (120 nm), and ITO (10 nm) are sequentially deposited to form a first electrode with an ITO/Ag/ITO structure. The compound represented by Chemical Formula A is deposited to form a 30 nm-thick hole auxiliary layer. Subsequently, on the hole auxiliary layer, Compound 3 (a p-type semiconductor) according to Synthesis Example 1 and C60 (an n-type semiconductor) are co-deposited in a thickness ratio (volume ratio) of 1:5.67 to form a 200 nm-thick photoelectric conversion layer (active layer). On the photoelectric conversion layer, C60 is deposited to form a 10 nm-thick electron auxiliary layer, and silver (Ag) is deposited to form a 30 nm-thick second electrode, manufacturing a photoelectric device. Subsequently, after forming a 50 nm-thick anti-reflection layer on the cathode by depositing aluminum oxide (Al₂O₃), an infrared sensor is manufactured by sealing with a glass plate. Herein, instead of Comparative Compound 11, each of the compounds according to the synthesis examples may be used in the same manner as above to manufacture an infrared sensor.

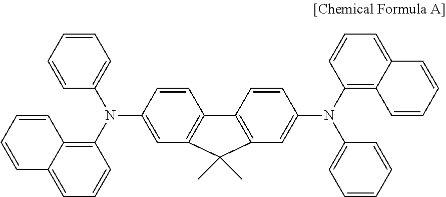 [SMILES: CC1(C)c2cc(N(c3ccccc3)c3cccc4ccccc34)ccc2-c2ccc(N(c3ccccc3)c3cccc4ccccc34)cc21]

### Examples 2-1 or 2-2

An infrared sensor is manufactured in the same manner as in Example 1 except that the compound of Synthesis Example 2-1 and the compound of Synthesis Example 2-2 are respectively used instead of the compound of Synthesis Example 1.

### Example 3

An infrared sensor is manufactured in the same manner as in Example 1 except that the compound of Synthesis Example 3 is used instead of the compound of Synthesis Example 1.

### Comparative Example 1

An infrared sensor is manufactured in the same manner as in Example 1 except that Comparative Compound 11 with the following structure (T2940 made by TCI) is used instead of the compound of Synthesis Example 1.

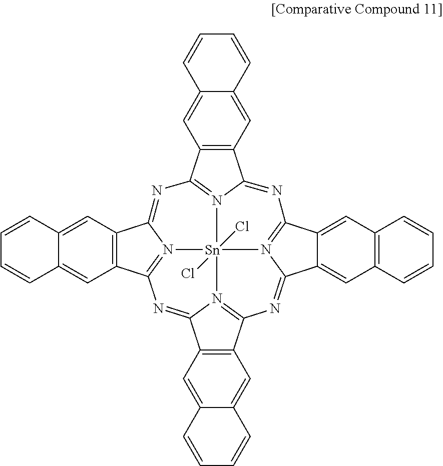

### Evaluation 1: Molecular Weight, Permanent Dipole Moment (PDM), and Aspect Ratio

The compounds and the comparative compounds with the structures described in Table 1 are evaluated with respect to a molecular weight, a permanent dipole moment (PDM), and an aspect ratio. The permanent dipole moment and the aspect ratio are calculated through Gaussian 16 program after optimizing a molecule structure using B3LYP/6_311 g (d,p) density function theory (DFT). The results are shown in Table 1.

TABLE 1

| | Compound | | Molecular | PDM | |
|---|---|---|---|---|---|
| | abbreviation | Compound structure | weight | (Debye) | Aspect ratio |
| Comparative Compound 1 | PP | 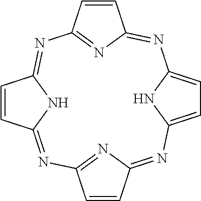 [SMILES: C1=Cc2nc1nc1ccc(nc3nc(nc4ccc(n2)[nH]4)C=C3)[nH]1] | 314 | 0.0004 | 2.0 |
| Comparative Compound 2 | PC | 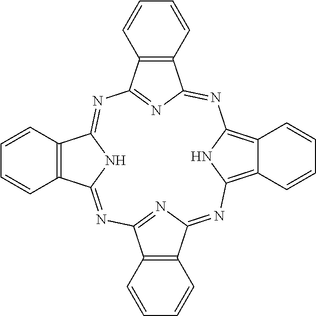 [SMILES: c1ccc2c(c1)-c1nc-2nc2[nH]c(nc3nc(nc4[nH]c(n1)c1ccccc41)-c1ccccc1-3)c1ccccc21] | 514 | 0.0001 | 2.0 |
| Comparative Compound 3 | NC | 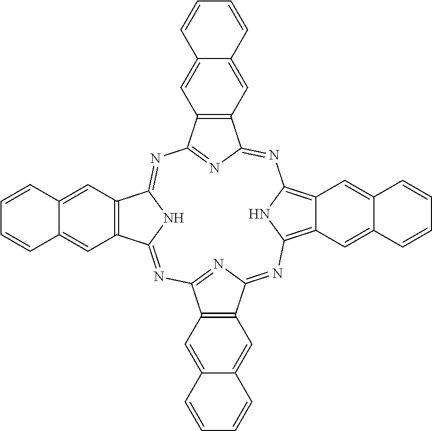 [SMILES: c1ccc2cc3c(cc2c1)-c1nc-3nc2[nH]c(nc3nc(nc4[nH]c(n1)c1cc5ccccc5cc41)-c1cc4ccccc4cc1-3)c1cc3ccccc3cc21] | 714 | 0.0006 | 2.0 |
| Comparative Compound 4 | PP_Zn | 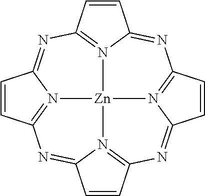 | 376 | 0.0025 | 2.0 |
| Comparative Compound 5 | PC_Zn | 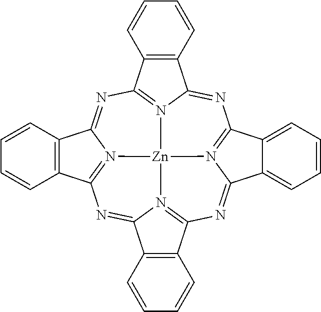 | 576 | 0.0016 | 2.0 |
| Comparative Compound 6 | NC_Zn | 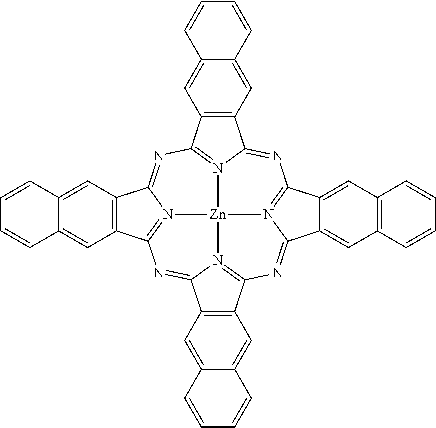 | 776 | 0.005 | 2.0 |
| Comparative Compound 7 | PC_Mn | 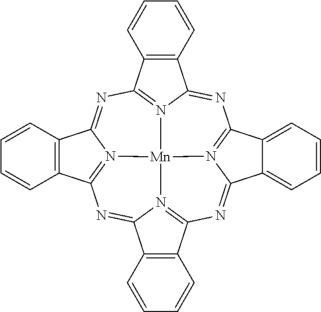 | 567 | 0.008 | 2.0 |
| Comparative Compound 8 | PP_Sn | 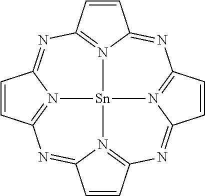 [SMILES: C1=C/C2=N/C3=[N]4->[Sn]56<-[N]2=C1/N=C1/C=CC(=[N]->51)/N=C1/C=CC(=[N]->61)/N=C4/C=C3] | 432 | 0.6114 | 1.8 |
| Comparative Compound 9 | PC_Sn | 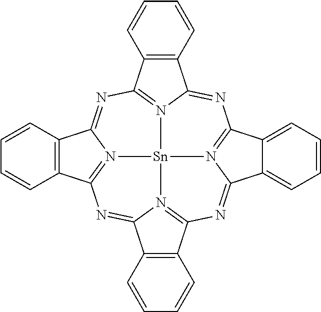 [SMILES: c1ccc2c(c1)C1=[N]3->[Sn]45<-[N]6=C(/N=C/23)c2ccccc2/C6=N/C2=[N]->4C(=N\C3=[N]->5C(=N\1)/c1ccccc13)/c1ccccc12] | 633 | 0.7745 | 1.9 |
| Comparative Compound 10 | NC_Sn | 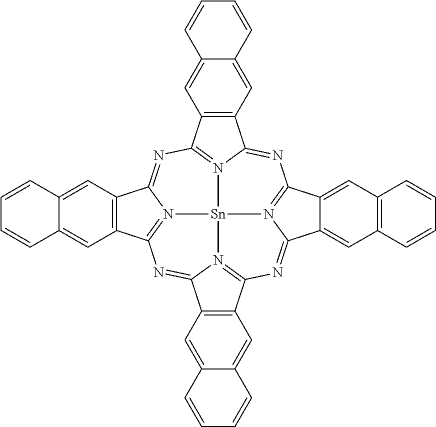 [SMILES: c1ccc2cc3c(cc2c1)C1=[N]2->[Sn]45<-[N]6=C(/N=C/32)c2cc3ccccc3cc2/C6=N/C2=[N]->4C(=N\C3=[N]->5C(=N\1)/c1cc4ccccc4cc13)/c1cc3ccccc3cc12] | 832 | 0.9381 | 1.9 |
| Comparative Compound 11 | NC_SnCl2 | 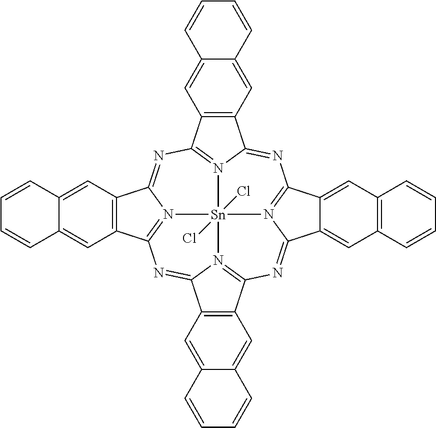 | 902 | 0.0004 | 1.9 |
| Compound 1 | aPC_AC1_free | 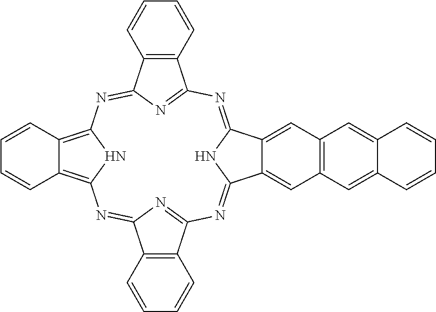 [SMILES: c1ccc2c(c1)-c1nc-2nc2[nH]c(nc3nc(nc4[nH]c(n1)c1ccccc41)-c1ccccc1-3)c1cc3cc4ccccc4cc3cc21] | 614 | 2.5804 | 3.4 |
| Compound 2 | aPP_AC1_Sn | 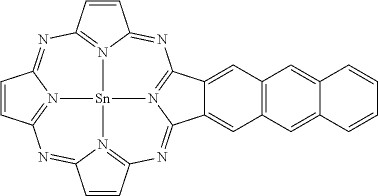 [SMILES: C1=C/C2=N/C3=[N]4->[Sn]56<-[N]2=C1/N=C1/C=CC(=[N]->51)/N=C1/c2cc5cc7ccccc7cc5cc2C(=[N]->61)/N=C4/C=C3] | 582 | 3.7541 | 5.7 |
| Compound 3 | aPC_AC1_Zn | 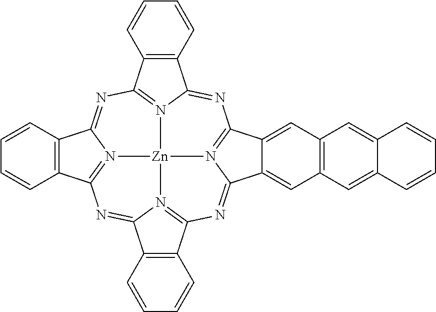 | 676 | 2.0852 | 3.4 |
| Compound 4 | aPC_TC1_Zn | 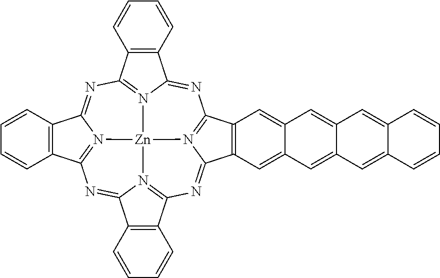 | 726 | 2.8176 | 4.5 |
| Compound 5 | aPC_AC1_Mn | 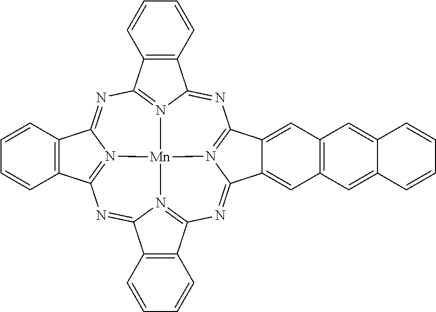 | 667 | 1.6992 | 3.4 |
| Compound 6 | aPC_TC1_Mn | 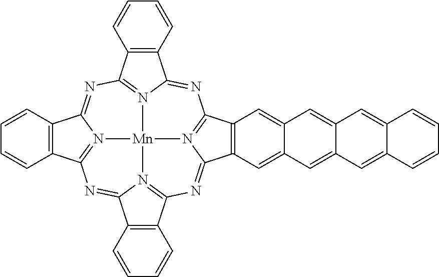 | 717 | 2.2840 | 4.5 |
| Compound 7 | aPC_AC1_Sn | 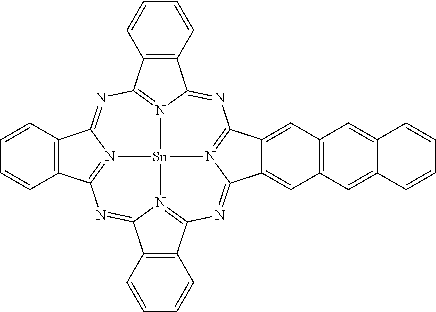 [SMILES: c1ccc2c(c1)C1=[N]3->[Sn]45<-[N]6=C(/N=C7/c8cc9cc%10ccccc%10cc9cc8C(=[N]->47)/N=C4/c7ccccc7C(=[N]->54)/N=C/23)c2ccccc2/C6=N/1] | 732 | 2.3274 | 3.2 |
| Compound 8 | aPC_AC2_Sn | 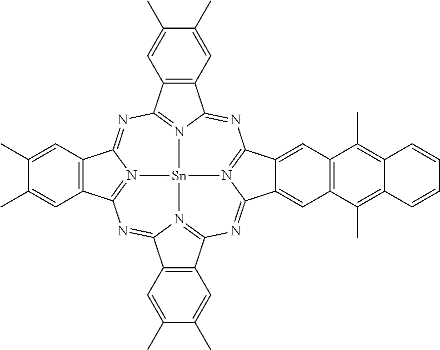 [SMILES: Cc1cc2c(cc1C)/C1=N/C3=[N]4->[Sn]56<-[N]1=C2/N=C1/c2cc(C)c(C)cc2C(=[N]->51)/N=C1/c2cc5c(C)c7ccccc7c(C)c5cc2C(=[N]->61)/N=C4/c1cc(C)c(C)cc13] | 844 | 1.4823 | 2.7 |
| Compound 9 | aPC_AC3_Sn | 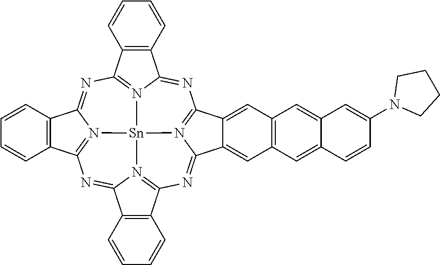 [SMILES: c1ccc2c(c1)C1=[N]3->[Sn]45<-[N]6=C(/N=C7/c8cc9cc%10ccc(N%11CCCC%11)cc%10cc9cc8C(=[N]->47)/N=C4/c7ccccc7C(=[N]->54)/N=C/23)c2ccccc2/C6=N/1] | 801 | 7.995 | 4.8 |
| Compound 10 | aPC_AC4_Sn | 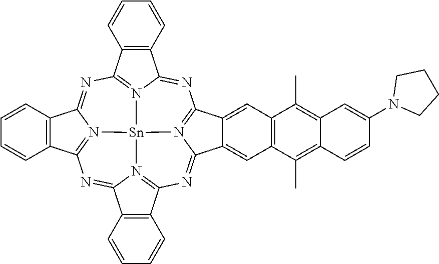 [SMILES: Cc1c2cc(N3CCCC3)ccc2c(C)c2cc3c(cc12)C1=[N]2->[Sn]45<-[N]6=C(/N=C7/c8ccccc8C(=[N]->47)/N=C/32)c2ccccc2/C6=N/C2=[N]->5C(=N\1)/c1ccccc12] | 829 | 8.3553 | 4.7 |
| Compound 11 | aPC_TC1_Sn | 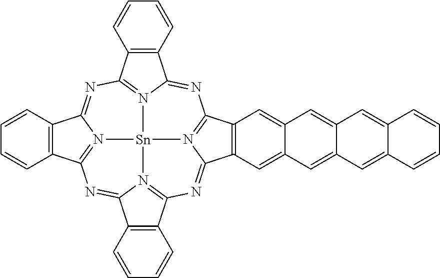 [SMILES: c1ccc2c(c1)C1=[N]3->[Sn]45<-[N]6=C(/N=C7/c8cc9cc%10cc%11ccccc%11cc%10cc9cc8C(=[N]->47)/N=C4/c7ccccc7C(=[N]->54)/N=C/23)c2ccccc2/C6=N/1] | 782 | 3.0800 | 4.3 |
| Compound 12 | aPC_AC1_SnC12 | 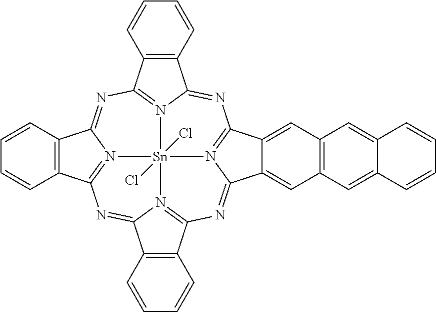 | 802 | 3.2481 | 3.2 |
| Compound 13 | aNC_AC1_Sn | 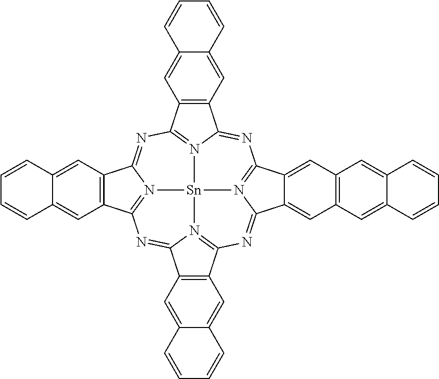 [SMILES: c1ccc2cc3c(cc2c1)C1=[N]2->[Sn]45<-[N]6=C(/N=C7/c8cc9cc%10ccccc%10cc9cc8C(=[N]->47)/N=C4/c7cc8ccccc8cc7C(=[N]->54)/N=C/32)c2cc3ccccc3cc2/C6=N/1] | 882 | 1.3747 | 2.3 |

Referring to Table 1, Compounds 1 to 13, which have an asymmetric structure and a molecular weight of 900 or less, may be easily used for a deposition process and in addition, which have a permanent dipole moment of 1.2 or more, and may be predicted to exhibit excellent absorption at a long wavelength and turn out to have an aspect ratio of greater than 2.0.

### Evaluation 2: Angle Between Permanent Dipole Moment (PDM) Direction and z-Axis

The compounds and comparative compounds with the structures described in Table 2 are calculated with respect to an angle between a direction of the permanent dipole moment (PDM) and a z-axis. The angle is calculated through Gaussian 16 program after optimizing the molecule structures by B3LYP/6_311g(d,p) density function theory (DFT). The results are shown in Table 2.

The angle is calculated according to Equation 1.

$$Angle = DEGREES ( ACOS ( SQRT ( {Z}^{2} ) / norm ) ) \qquad [ Equation 1 ]$$

$$Norm = SQRT ( {X}^{2} + {Y}^{2} + {Z}^{2} )$$

TABLE 2

| | | | | | Angle |
|---|---|---|---|---|---|
| | | | | | between |
| | | | | | PDM and |
| | PDM (Debye) | | | | z-axis |
| | x | y | z | norm | (degree) |
| Comparative Compound 11 | 0 | −0.0001 | 0.0003 | 0.0003 | 18.43 |
| Compound 3 aPC_AC1_Zn | 2.0852 | 0 | −0.0005 | 2.0852 | 89.99 |
| Compound 5 aPC_AC1_Mn | −1.6991 | −0.0001 | −0.0002 | 1.6991 | 89.99 |
| Compound 7 aPC_AC1_Sn | 2.202 | 0 | −0.7535 | 2.3274 | 71.11 |
| Compound 12 aPC_AC1_SnCl2 | 3.2481 | 0 | 0.0018 | 3.2481 | 89.97 |
| Compound 14 aPC_AC1_Al | 2.762 | 0.0003 | −4.4195 | 5.2116 | 32.00 |

Referring to Table 2, Compounds 3, 5, 7, 12, and 14 with an asymmetric structure have an angle between PDM and z-axis of 32° or more, but Comparative Compound 11 has an angle of 18.43°.

### Evaluation 3: Absorption Wavelength

An absorption wavelength of Compounds 1 to 13 is calculated by B3LYP/6_311g(d,p) density function theory (DFT). Among them, the results of Compounds 4, 6, and 8 to 13 are shown in Table 3. For comparison, an absorption wavelength of Comparative Compound 11 is also calculated, and the result is shown in Table 3.

TABLE 3

| | | | Absorption |
|---|---|---|---|
| | Compound | | wavelength |
| | abbreviation | Compound structure | (λₘₐₓ, nm) |
| Comparative Compound 11 | NC_SnCl2 | 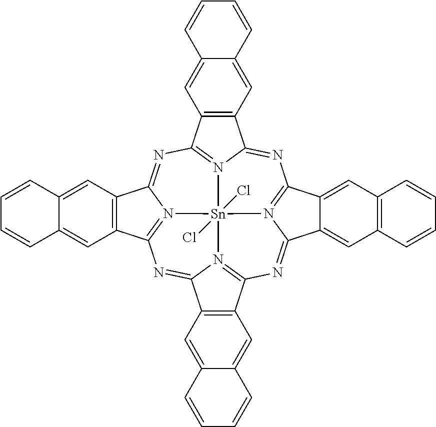 | 734 |
| Compound 4 | aPC_AC5_Zn | 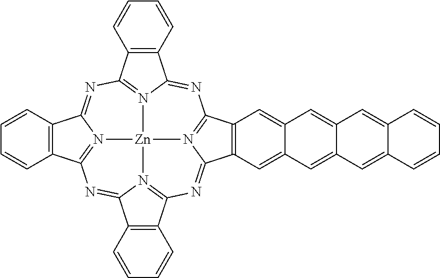 | 750 |
| Compound 6 | aPC_AC5_Mn | 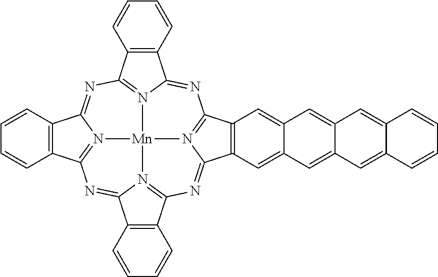 | 751 |
| Compound 8 | aPC_AC2_Sn | 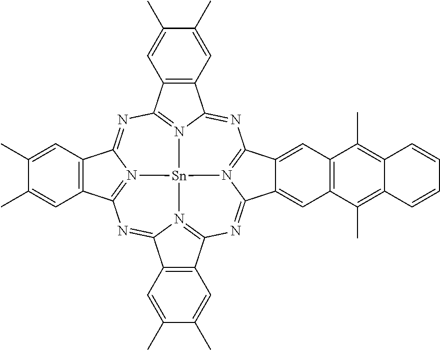 [SMILES: Cc1cc2c(cc1C)/C1=N/C3=[N]4->[Sn]56<-[N]1=C2/N=C1/c2cc(C)c(C)cc2C(=[N]->51)/N=C1/c2cc5c(C)c7ccccc7c(C)c5cc2C(=[N]->61)/N=C4/c1cc(C)c(C)cc13] | 748 |
| Compound 9 | aPC_AC3_Sn | 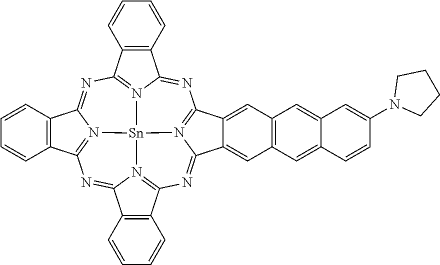 [SMILES: c1ccc2c(c1)C1=[N]3->[Sn]45<-[N]6=C(/N=C7/c8cc9cc%10ccc(N%11CCCC%11)cc%10cc9cc8C(=[N]->47)/N=C4/c7ccccc7C(=[N]->54)/N=C/23)c2ccccc2/C6=N/1] | 784 |
| Compound 10 | aPC_AC4_Sn | 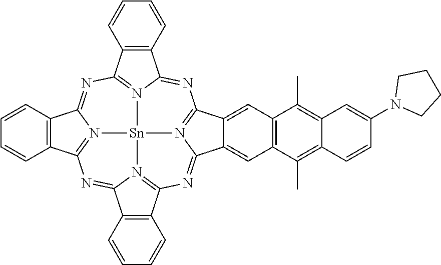 [SMILES: Cc1c2cc(N3CCCC3)ccc2c(C)c2cc3c(cc12)C1=[N]2->[Sn]45<-[N]6=C(/N=C7/c8ccccc8C(=[N]->47)/N=C/32)c2ccccc2/C6=N/C2=[N]->5C(=N\1)/c1ccccc12] | 813 |
| Compound 11 | aPC_AC5_Sn | 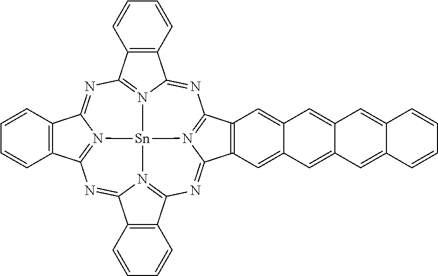 [SMILES: c1ccc2c(c1)C1=[N]3->[Sn]45<-[N]6=C(/N=C7/c8cc9cc%10cc%11ccccc%11cc%10cc9cc8C(=[N]->47)/N=C4/c7ccccc7C(=[N]->54)/N=C/23)c2ccccc2/C6=N/1] | 801 |
| Compound 13 | aNC_AC1_Sn | 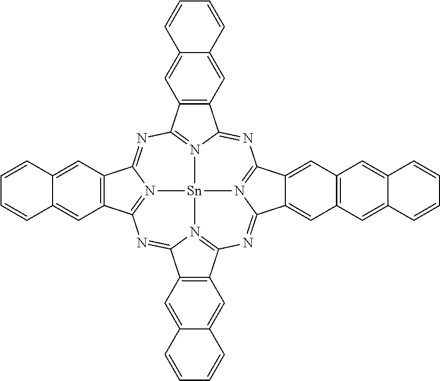 [SMILES: c1ccc2cc3c(cc2c1)C1=[N]2->[Sn]45<-[N]6=C(/N=C7/c8cc9cc%10ccccc%10cc9cc8C(=[N]->47)/N=C4/c7cc8ccccc8cc7C(=[N]->54)/N=C/32)c2cc3ccccc3cc2/C6=N/1] | 807 |

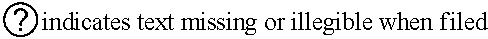

Referring to Table 3, the absorption wavelengths of Compounds 4, 6, and 8 to 13, compared with that of Comparative Compound 11, have a maximum absorption wavelength (λₘₐₓ) in a long wavelength region.

An infrared sensor including Comparative Compound 11 is measured with respect to external quantum efficiency (EQE) by using an IPCE measurement system (TNE Tech Co., Ltd., Korea). After calibrating the system by using an Si photodiode (Hamamatsu Photonics K.K., Japan) and mounting the infrared sensor thereon, the external quantum efficiency (EQE) is measured in a wavelength region of about 400 nm to about 1400 nm to evaluate a wavelength expressing the maximum external quantum efficiency (EQEₘₐₓ).

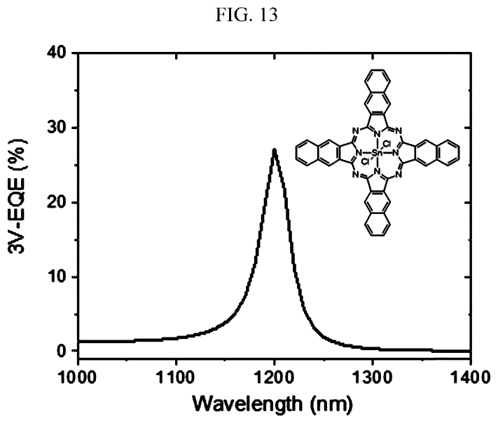

The results are shown in FIG. 13. FIG. 13 shows the results of measuring the external quantum efficiency of the infrared sensor according to Comparative Example 1.

Referring to Table 3 and FIG. 13, because the calculated maximum absorption wavelength of Compounds 4, 6, and 8 to 13 is longer than that of Comparative Compound 11, wherein the infrared sensor including Comparative Compound 11 exhibits maximum external quantum efficiency at about 1200 nm, the infrared sensors respectively including Compound 4, 6, and 8 to 13 are expected to exhibit maximum external quantum efficiency in an infrared absorption wavelength region.

While the inventive concepts have been described in connection with what is presently considered to be practical example embodiments, it is to be understood that the inventive concepts are not limited to such example embodiments, but, on the contrary, are intended to cover various modifications and equivalent arrangements included within the spirit and scope of the appended claims.

<Description of symbols>

| | |
|---|---|
| 10: first electrode | 20: second electrode |
| 31: infrared photoelectric conversion layer | 32, 33: auxiliary layer |
| 40: semiconductor substrate | 55, 240: charge storage |
| 70: color filter layer | 60, 80: insulating layer |
| 85, 87: trench | 100: infrared sensor |
| 200: visible light sensor | 230: visible photoelectric |
| | conversion layer |
| 250: optical filter | 300: CMOS infrared sensor |
| 400: combination sensor | |

What is claimed is:

1. An infrared sensor, comprising:
a first electrode and a second electrode facing each other, and
an infrared photoelectric conversion layer located between the first electrode and the second electrode, the infrared photoelectric conversion layer including a compound represented by Chemical Formula 1, 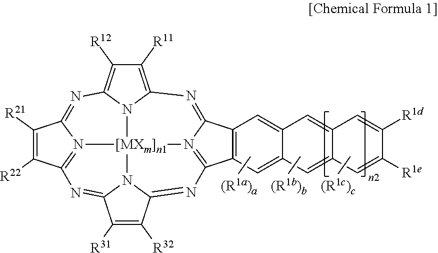
wherein, in Chemical Formula 1,
M is a divalent metal, a trivalent metal, or a tetravalent metal,
X is a halogen,
m is an integer from 0 to 4,
n1 is 0 or 1,
R^{1a}, R^{1b}, R^{1c}, R^{1d}, and R^{1e} are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof,
a, b, and c are each independently an integer from 0 to 2,
n2 is 1 or 2, and
R¹¹, R¹², R²¹, R²², R³¹, and R³² are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof, or at least one pair of a pair of R¹¹ and R¹², a pair of R²¹ and R²², or a pair of R³¹ and R³² are linked to each other to form a substituted or unsubstituted benzene ring or a substituted or unsubstituted naphthalene ring.

2. The infrared sensor of claim 1, wherein
in Chemical Formula 1, M is a transition metal.

3. The infrared sensor of claim 1, wherein
in Chemical Formula 1, M is Zn, Mn, Sn, Co, Ru, Ni, V, Si, or Ge.

4. The infrared sensor of claim 1, wherein
a molecular weight of the compound represented by Chemical Formula 1 is less than or equal to about 900.

5. The infrared sensor of claim 1, wherein
the compound represented by Chemical Formula 1 has a permanent dipole moment of greater than or equal to about 1.2 Debye.

6. The infrared sensor of claim 1, wherein
the compound represented by Chemical Formula 1 has an aspect ratio of greater than about 2.0 and less than or equal to about 8.0.

7. The infrared sensor of claim 1, wherein
the compound represented by Chemical Formula 1 has a sublimation temperature of less than or equal to about 500° C., wherein the sublimation temperature refers to a temperature at which a weight loss of the compound represented by Chemical Formula 1 of 5% compared to an initial weight of the compound represented by Chemical Formula 1 occurs when thermogravimetric analysis of the compound represented by Chemical Formula 1 occurs at 10 Pa or less.

8. The infrared sensor of claim 1, wherein
a maximum external quantum efficiency (EQEₘₐₓ) wavelength of the infrared sensor is in a wavelength range of about 800 nm to about 3000 nm.

9. The infrared sensor of claim 1, wherein
the infrared photoelectric conversion layer further includes a counter material that forms a pn junction with the compound.

10. The infrared sensor of claim 1, wherein
the infrared sensor further includes an auxiliary layer that is at least one of
between the first electrode and the infrared photoelectric conversion layer, or
between the second electrode and the infrared photoelectric conversion layer.

11. The infrared sensor of claim 10, wherein
the auxiliary layer includes ytterbium (Yb), calcium (Ca), potassium (K), barium (Ba), magnesium (Mg), lithium fluoride (LiF), or an alloy thereof.

12. The infrared sensor of claim 1, further comprising:
a semiconductor substrate.

13. A combination sensor, comprising:
a first infrared sensor, and
a second infrared sensor configured to sense light in a shorter wavelength region or a longer wavelength region than the first infrared sensor within an infrared wavelength region,
wherein the first infrared sensor is the infrared sensor of claim 1, and
wherein the first infrared sensor and the second infrared sensor are stacked in a depth direction that is perpendicular to an in-plane direction of the first infrared sensor.

14. A combination sensor, comprising:
the infrared sensor of claim 1, and
a visible light sensor configured to sense at least a portion of light in a visible light wavelength region.

15. An electronic device comprising the infrared sensor of claim 1.

16. An electronic device comprising the combination sensor of claim 13.

17. A compound represented by Chemical Formula 1: 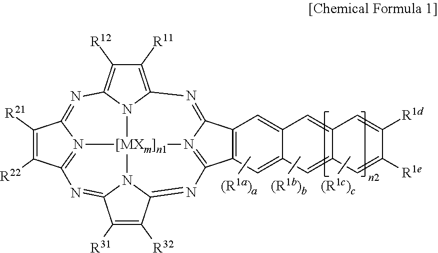
wherein, in Chemical Formula 1,
M is a divalent metal, a trivalent metal, or a tetravalent metal,
X is a halogen,
m is an integer from 0 to 4,
n1 is 0 or 1,
R^{1a}, R^{1b}, R^{1c}, R^{1d}, and R^{1e} are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof,
a, b, and c are each independently an integer from 0 to 2,
n2 is 1 or 2, and
R¹¹, R¹², R²¹, R²², R³¹, and R³² are each independently hydrogen, deuterium, a halogen, a C1 to C20 haloalkyl group, a cyano group (—CN), a C1 to C20 cyanoalkyl group, a C1 to C20 alkyl group, a hydroxy group, a C1 to C20 alkoxy group, a C6 to C20 aryl group, a C3 to C20 heteroaryl group, a C3 to C30 cycloalkyl group, a C3 to C30 heterocycloalkyl group, an amine group, an ester group, an amide group, a thiol group, a thioalkyl group, a thioester group, or any combination thereof, or at least one pair of a pair of R¹¹ and R¹², a pair of R²¹ and R²², or a pair of R³¹ and R³² are linked to each other to form a substituted or unsubstituted benzene ring or a substituted or unsubstituted naphthalene ring.

18. The compound of claim 17, wherein
in Chemical Formula 1, M is a transition metal.

19. The compound of claim 17, wherein
in Chemical Formula 1, M is Zn, Mn, Sn, Co, Ru, Ni, V, Si, or Ge.

20. The compound of claim 17, wherein the compound has at least one of
a molecular weight that is less than or equal to about 900,
a permanent dipole moment of greater than or equal to about 1.2 Debye, or
an aspect ratio of greater than about 2.0 and less than or equal to about 8.0.
